(19) United States
(12) Patent Application Publication
(10) Pub. No.: US 2026/0041005 A1
(43) Pub. Date: Feb. 5, 2026

(54) HYBRID BONDING TECHNIQUES FOR STACKED SEMICONDUCTOR SYSTEMS

(71) Applicant: Micron Technology, Inc., Boise, ID (US)

(72) Inventors: Youngrae Kim, Taichung (TW); Sui Chi Huang, Taichung (TW)

(21) Appl. No.: 19/274,342

(22) Filed: Jul. 18, 2025

Related U.S. Application Data
(60) Provisional application No. 63/677,335, filed on Jul. 30, 2024.

(51) Int. Cl. H01L 25/16; H01L 21/56; H01L 23/00; H01L 23/31; H10B 80/00

(52) U.S. Cl. CPC H01L 25/16; H01L 21/56; H01L 23/3135; H01L 24/08; H01L 24/80; H10B 80/00; H01L 2224/08145; H01L 2224/80895; H01L 2224/80896

(57) ABSTRACT

Methods, systems, and devices for hybrid bonding techniques for stacked semiconductor systems are described. A semiconductor device may be formed to include a stack of memory array dies. Each memory array die of the stack may be bonded with at least one other memory array die in the stack. The semiconductor device may include a set of multiple dielectric material portions, with each dielectric material portion extending beyond a lateral boundary of the stack and extending from a respective semiconductor substrate portion of a corresponding memory array die. The semiconductor device may also include a logic die bonded with a first memory array die of the stack, and the logic die may include circuitry operable to facilitate one or more access operations of the memory array dies of the stack.

### CROSS REFERENCE

The present Application for Patent claims priority to U.S. Patent Application No. 63/677,335 by Kim et al., entitled “HYBRID BONDING TECHNIQUES FOR STACKED SEMICONDUCTOR SYSTEMS,” filed Jul. 30, 2024, which is assigned to the assignee hereof, and which is expressly incorporated by reference in its entirety herein.

### TECHNICAL FIELD

The following relates to one or more semiconductor systems, including hybrid bonding techniques for stacked semiconductor systems.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports hybrid bonding techniques for stacked semiconductor systems in accordance with examples as disclosed herein.

FIG. 2 shows an example of a system that supports hybrid bonding techniques for stacked semiconductor systems in accordance with examples as disclosed herein.

FIGS. 3A through 3J illustrate examples of operations that support hybrid bonding techniques for stacked semiconductor systems in accordance with examples as disclosed herein.

FIGS. 4A through 4L illustrate examples of operations that support hybrid bonding techniques for stacked semiconductor systems in accordance with examples as disclosed herein.

FIGS. 5 and 6 show flowcharts illustrating a method or methods that support hybrid bonding techniques for stacked semiconductor systems in accordance with examples as disclosed herein.

### DETAILED DESCRIPTION

Some semiconductor systems (e.g., memory systems, processor systems) may include a stack of semiconductor components (e.g., semiconductor dies), which may include one or more dies (e.g., dynamic random access memory (DRAM) dies, memory array dies, array dies, memory dies) that are stacked with (e.g., over) a logic die that is operable to access a set of memory arrays distributed across the one or more memory dies. Such a stacked architecture may be implemented as part of a high bandwidth memory (HBM) system or a coupled dynamic random access memory (DRAM) system, among other examples, and may support solutions for memory-centric logic, such as graphics processing units (GPUs), among other implementations. In some examples, an HBM system may include one or more memory dies coupled (e.g., bonded, stacked) with a logic die. In some examples, a 3D stacked memory system may be closely coupled (e.g., physically coupled, electrically coupled, directly coupled) with a processor, such as a GPU or other host device, as part of a physical memory map accessible to the processor. A logic die may include various components such as interface blocks (e.g., memory interface blocks, interface circuitry), logic blocks, controllers, processors, and other components. A semiconductor component (e.g., a semiconductor unit, a semiconductor subsystem), such as a logic die, may be formed as a single die with relevant circuitry, or may be formed with multiple die portions (e.g., relatively smaller dies, dies each including a respective subset of components of a logic unit) that may be referred to as “chiplets” (e.g., logic chiplets), among other examples.

Semiconductor dies (e.g., DRAM dies, logic dies) associated with a stacked semiconductor device (e.g., 3D stacked memory, HBM, or other stacked memory system) may be bonded via various techniques. Some bonding techniques (e.g., hybrid bonding) may be associated with a bonding (e.g., fusion) of respective material types (e.g., a dielectric material bonding and a conductive material bonding) of respective semiconductor dies (e.g., without an intermediate layer between the dies). In some cases, manufacturing operations performed during device fabrication (e.g., etching operations, grinding operations, cutting operations, deposition operations, and other operations) may produce debris (e.g., debris particles). Such debris may collect on one or more respective surfaces of semiconductor dies prior to bonding. A collection of debris (or other foreign particles) may adversely affect electrical characteristics of one or more of the bonded dies (e.g., by inhibiting one or more electrical connections between the bonded dies) causing the device to be rejected and discarded. Some cleaning operations may be utilized to remove some of the particles. However, cleaning operations may, in some cases, cause damage (e.g., breakage) to a die surface, may not sufficiently clean the particles from the surface, or may be associated with other deficiencies.

In accordance with one or more techniques described herein, a semiconductor device may be manufactured using various operations (e.g., bonding techniques) to mitigate particle collection, improve reliability of the semiconductor device, or improve a manufacturing yield, among other benefits. Such operations may include wafer reconstruction operations (e.g., reconstruction of known-good-dies (KGDs)), planarizing operations (e.g., chemical mechanical planarization (CMP)), and bonding operations (e.g., wafer-to-wafer (W2W) bonding, chip-to-wafer (C2W) bonding, stack-to-wafer (S2W) bonding). In some examples, a first set of memory array dies (e.g., DRAM dies, KGDs, core dies) may be bonded to a carrier to form a reconstructed wafer (e.g., after covering the memory dies with one or more dielectric materials), which may also be planarized (e.g., and polished) before bonding (e.g., which may remove a significant portion of debris particles). Subsequently, one or more additional sets of memory array dies may be bonded to the first set of memory array dies to form a stack of memory array dies of a semiconductor device.

Additional sets of memory array dies may be bonded with the first set after being formed as a reconstructed wafer (e.g., one or more second dielectric materials may be formed around the additional dies before bonding, via W2W bonding), or each die may be individually bonded to a respective die of the first set (e.g., one or more second dielectric materials may be formed around the additional dies after bonding, via C2W bonding). The stack of memory array dies may be bonded with a logic wafer, and one or more molding compounds may be formed over the stack of memory dies and the logic wafer. Thus, by utilizing one or more techniques herein, stacked semiconductor devices may be manufactured with increased reliability (e.g., based on reduced particle collection), increased structural integrity, and improved device yield, among other benefits.

In addition to applicability in memory systems as described herein, techniques for hybrid bonding for stacked semiconductor systems may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by improving structural integrity during processing and reducing materials (e.g., rejected materials) used in production of electronic devices, which may result in reduced electronic waste and extended the life of electronic devices, among other benefits.

Features of the disclosure are illustrated and described in the context of systems and architectures. Features of the disclosure are further illustrated and described in the context of devices and flowcharts.

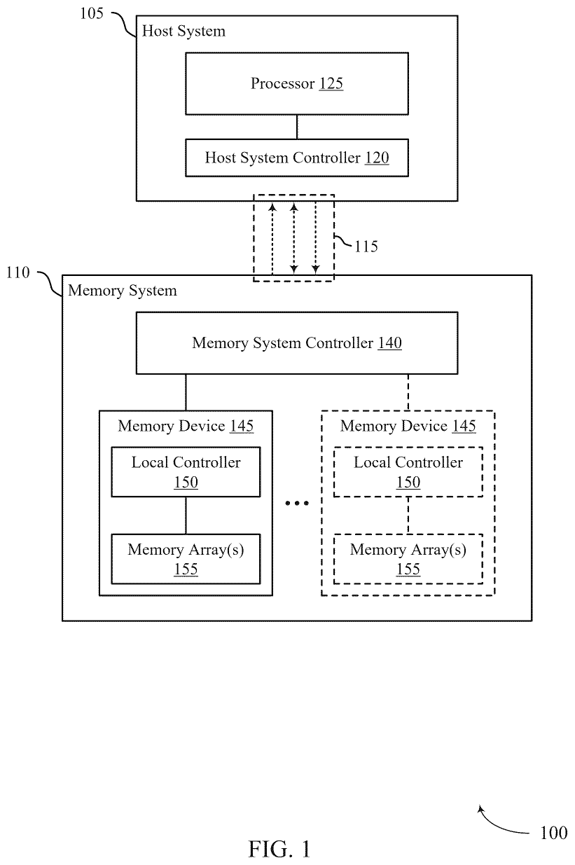

FIG. 1 shows an example of a system 100 that supports hybrid bonding techniques for stacked semiconductor systems in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

In some examples, the system 100 or the host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or a combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, portions of a memory die) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

Signaling may be communicated over the channels 115 using single data rate (SDR) signaling or double data rate (DDR) signaling, among other rates (e.g., relative to a clock signal). In SDR signaling, one modulation symbol (e.g., signal level) of a signal may be registered for each clock cycle (e.g., on a rising edge or a falling edge of a clock signal). In DDR signaling, two modulation symbols of a signal may be registered for each clock cycle (e.g., on both a rising edge and a falling edge of a clock signal).

In some examples, at least a portion of the system 100 may implement a stacked semiconductor architecture in which multiple semiconductor dies are physically and communicatively coupled (e.g., directly coupled, bonded). For example, at least one of the memory arrays 155 of a memory device 145 may be formed using one or more semiconductor dies (e.g., a single memory die, a stack of multiple memory dies), which may be stacked over another semiconductor die (e.g., a logic die) that includes at least a portion of a local controller 150. In some examples, a semiconductor die or die assembly may include at least a portion of or all of a local controller 150 and at least a portion of or all of a memory system controller 140, and such a semiconductor die or die assembly may be coupled with one or more memory dies, or one or more stacks of memory dies (e.g., one or more memory stacks). In accordance with these and other examples, circuitry for accessing one or more memory arrays 155 (e.g., circuitry of a memory system 110) may be distributed among multiple semiconductor dies of a stack (e.g., a stack of multiple directly-coupled semiconductor dies). For example, a first die may include a set of multiple first interface blocks (e.g., memory interface blocks, instances of first interface circuitry) and one or more second dies may include corresponding second interface blocks, each coupled with a first interface block of the first die, which are each configured to access one or more memory arrays 155 of the second dies. In some examples, the system may include a controller (e.g., a memory controller, an interface controller, a host interface controller, at least a portion of a memory system controller 140) for each set of one or more first interface blocks to support access operations (e.g., to access one or more memory arrays 155) via the set of first interface blocks. In some examples, such a controller may be located in the same first die as the first interface blocks. In some examples, multiple semiconductor dies of a memory system 110 or of a system 100 (e.g., an HBM system including aspects of a memory system 110, a 3D stacked memory system including aspects of a memory system 110 and a host system 105) may include one or more array dies stacked with a logic die (e.g., that includes aspects of the host system 105, that is coupled with another die that includes the host system 105) that includes interface blocks operable to access a set of memory arrays 155 distributed across the one or more second dies.

Some semiconductor dies (e.g., DRAM dies, dies of a memory system 110, dies of a host system 105) associated with a system 100 (e.g., a 3D stacked memory system, an HBM system, or other stacked memory system) may be bonded via various techniques. However, some manufacturing operations performed during device production may produce debris, which may collect on one or more respective surfaces of semiconductor dies prior to bonding. A collection of debris or other foreign particles may adversely affect electrical characteristics of one or more of the bonded dies (e.g., by inhibiting one or more electrical connections between the bonded dies), which may cause the device to be rejected and discarded. Some cleaning operations may be utilized to remove some of the particles. However, such cleaning operations may cause damage may not sufficiently remove the debris from the surface.

In accordance with one or more techniques described herein, a semiconductor device (e.g., a system 100 or a component therein) may be manufactured using various operations (e.g., bonding techniques) improve reliability of the semiconductor device. Such operations may include wafer reconstruction operations (e.g., reconstruction of KGDs), planarizing operations (e.g., CMP), and bonding operations (e.g., W2W bonding, C2W bonding, S2W bonding). In some examples, a first set of memory array dies may be bonded to a carrier to form a reconstructed wafer (e.g., after covering the memory dies with one or more dielectric materials), which may be planarized (e.g., and polished) before bonding (e.g., which may also remove debris particles). Subsequently, one or more additional sets of memory array dies may be bonded to the first set of memory array dies to form a stack of memory array dies of a semiconductor device.

Additional sets of memory array dies may be bonded with the first set after being formed as a reconstructed wafer (e.g., one or more second dielectric materials may be formed around the additional dies before bonding, via W2W bonding), or each die may be individually bonded to a respective die of the first set (e.g., one or more second dielectric materials may be formed around the additional dies after bonding, via C2W bonding). The stack of memory array dies may be bonded with a logic wafer (e.g., or a host wafer), and one or more molding compounds may be formed over the stack of memory dies and the logic wafer. Thus, by utilizing one or more techniques herein, systems 100 may be manufactured with increased reliability (e.g., based on reduced particle collection), increased structural integrity, and improved device yield, among other benefits.

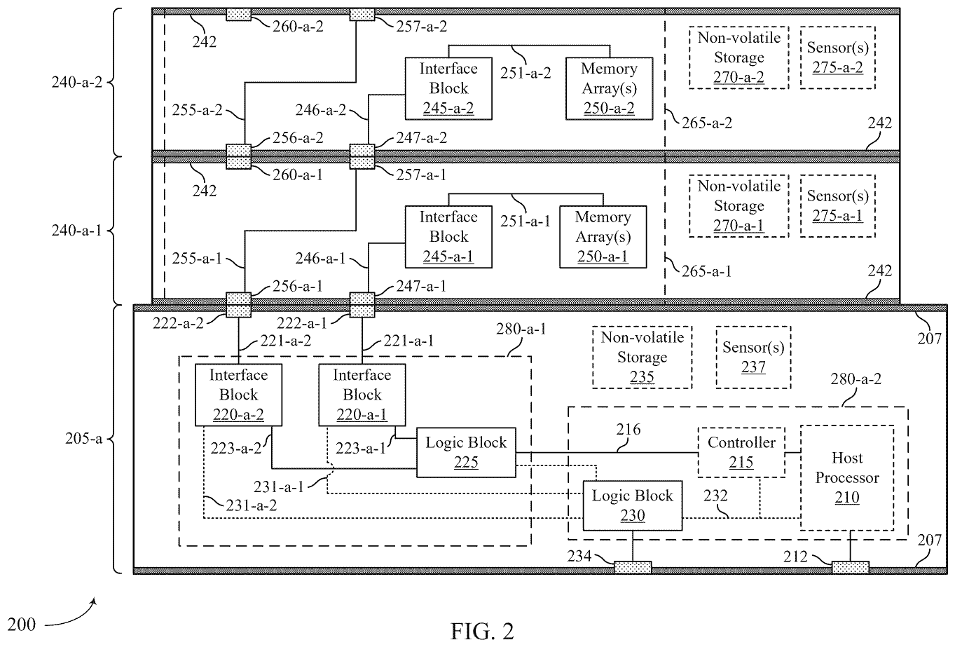

FIG. 2 shows an example of a system 200 (e.g., a semiconductor system, a system of coupled semiconductor dies, an HBM system, a 3D stacked memory system) that supports hybrid bonding techniques for stacked semiconductor systems in accordance with examples as disclosed herein. The system 200 illustrates an example of a die 205 (e.g., a die 205-a, a semiconductor die, a logic die, a processor die, a host die, a logic unit) that is coupled with one or more dies 240 (e.g., dies 240-a-1 and 240-a-2, semiconductor dies, memory dies, array dies, memory units, of a memory stack). A die 205 or a die 240 may be formed using a respective semiconductor substrate (e.g., a substrate of crystalline semiconductor material such as silicon, germanium, silicon-germanium, gallium arsenide, or gallium nitride), or a silicon-on-insulator (SOI) substrate (e.g., silicon-on-glass (SOG), silicon-on-sapphire (SOS)), or epitaxial semiconductor materials formed on another substrate, among other examples. Although the illustrated example of a system 200 includes two dies 240, a system 200 in accordance with the described techniques may include any quantity of one or more dies 240 (e.g., 8, 12, 16, or more dies 240) coupled with a die 205, among other dies of a stack or other coupled layout. Further, although non-limiting examples of the system 200 herein are generally described in terms of applicability to memory systems, memory sub-systems, memory devices, or a combination thereof, examples of the system 200 are not so limited. For example, aspects of the present disclosure may be applied as well to any computing system, computing sub-system, processing system, processing sub-system, component, device, structure, or other types of systems or sub-systems used for applications such as data collecting, data processing, data storage, networking, communication, power, artificial intelligence, system-on-a-chip, control, telemetry, sensing and monitoring, digital entertainment, or any combination thereof.

The system 200 illustrates an example of interface circuitry between a host and memory (e.g., via a host interface, via a physical host interface) that is implemented in (e.g., divided between) multiple semiconductor dies (e.g., a stack of directly-coupled dies). For example, the die 205-a may include a set of one or more interface blocks 220 (e.g., interface blocks 220-a-1 and 220-a-2, memory interface blocks), and each die 240 may include a set of one or more interface blocks 245 (e.g., access interface blocks) and one or more memory arrays 250 (e.g., die 240-a-1 including an interface block 245-a-1 coupled with a set of one or more memory arrays 250-a-1, die 240-a-2 including an interface block 245-a-2 coupled with a set of one or more memory arrays 250-a-2). The memory arrays 250 may be examples of memory arrays 155, and may include memory cells of various architectures, such as RAM, DRAM, SDRAM, SRAM, FeRAM, MRAM, RRAM, PCM, chalcogenide, NOR, or NAND memory cells, or any combination thereof.

Although the example of system 200 is illustrated with one interface block 245 included in each die 240, a die 240 in accordance with the described techniques may include any quantity of one or more interface blocks 245, each coupled with a respective set of one or more memory arrays 250, and each coupled with an interface block 220 of a die 205. Thus, the interface circuitry of a system 200 may include one or more interface blocks 220 of a die 205, with each interface block 220 being coupled with (e.g., in communication with) one or more interfaces block 245 of a die 240 (e.g., external to the die 205). In some examples, a coupled combination of an interface block 220 and an interface block 245 (e.g., coupled via a bus associated with one or more channels, such as one or more data channels, one or more control channels, one or more clock channels, one or more pseudo-channels, or a combination thereof) may include or be referred to as a data path associated with a respective set of one or more memory arrays 250.

In some implementations (e.g., 3D stacked memory implementations), a die 205 may include a host processor 210. A host processor 210 may be an example of a host system 105, or a portion thereof (e.g., a processor 125, aspects of a host system controller 120, or both). A host processor 210 may include one or more processor cores that are configured to perform operations that implement storage of the memory arrays 250 (e.g., to support an application or other function of a host system 105, which may request access to the memory arrays 250). For example, the host processor 210 may receive data read from the memory arrays 250, or may transmit data to be written to the memory arrays 250, or both (e.g., in accordance with an application or other operations of the host processor 210). Additionally, or alternatively, a host processor 210 may be external to a die 205 (e.g., in HBM implementations), such as in another semiconductor die or other component that is coupled with (e.g., communicatively coupled with, directly coupled with, bonded with, coupled via another intervening component) the die 205 via one or more contacts 212 (e.g., externally-accessible terminals of the die 205).

A host processor 210 may be configured to communicate (e.g., transmit, receive) signaling with interface blocks 220 via a host interface 216 (e.g., a physical host interface), which may implement aspects of channels 115. For example, a host interface 216 may be configured in accordance with an industry standard, which may define channels, commands, clocking, and deterministic responses and timing, among other characteristics of the host interface 216. In some examples, a host interface 216 may provide a communicative coupling between physical or functional boundaries of a host system 105 and a memory system 110. For example, the host processor 210 may be configured to communicate access signaling (e.g., control signaling, access command signaling, data signaling, configuration signaling, clock signaling) via a host interface 216 to support access operations (e.g., read operations, write operations) on the memory arrays 250, among other operations. Although the example of system 200 includes a single host interface 216, a system in accordance with the described techniques may include any quantity of one or more host interfaces 216 for accessing memory arrays 250 of the system.

In some examples, a respective host interface 216 may be coupled between a set of one or more interface blocks 220 (e.g., interface blocks 220-a-1 and 220-a-2) and a respective controller 215. A controller 215 may be an example of control circuitry (e.g., memory controller circuitry, host interface control circuitry) associated with a host system 105, and may be associated with implementing respective instances of one or more aspects of a host system controller 120, or of a memory system controller 140, or a combination thereof. For example, a controller 215 may be operable to respond to indications (e.g., requests, commands) from the host processor 210 to access one or more memory arrays 250 in support of a function or application of the host processor 210, to transmit associated commands (e.g., for one or more interface blocks 220) to access the one or more memory arrays 250, and to communicate data (e.g., write data, read data) with the host processor 210, among other functions.

In some examples, one or more controllers 215 may be implemented in a die 205 (e.g., the same die that includes one or more interface blocks 220, in a 3D stacked memory implementation, in accordance with a command and address protocol) whether a host processor 210 is included in the die 205, or is external to the die 205. In some other examples, controllers 215 or associated circuitry or functionality may be implemented external to a die 205 (e.g., in another die, not shown, coupled with respective interface blocks 220 via respective terminals for each of the respective host interfaces 216, in an HBM implementation), which may be in the same die as or a different die from a die that includes a host processor 210. An interface block 220 may be operable via a single controller 215, or by one or more of a set of multiple controllers 215 (e.g., in accordance with a controller multiplexing scheme). In some other examples, aspects of one or more controllers 215 may be included in the host processor 210 (e.g., as a memory interface of the host processor 210, as a memory interface of a host system 105).

Although, in some examples, a controller 215 may be directly coupled with one or more interface blocks 220 (not shown), in some other examples, a controller 215 (e.g., a host interface 216) may be coupled with a set of multiple interface blocks 220 via a logic block 225 (e.g., logic circuitry for a channel set, logic circuitry for a host interface 216, multiplexing circuitry). For example, the logic block 225 may be coupled with the interface block 220-a-1 via a bus 223-a-1 and coupled with the interface block 220-a-2 via a bus 223-a-2. A controller 215 and one or more corresponding interface blocks 220 and may communicate (e.g., collaborate) using the host interface 216 via a logic block 225 to perform one or more operations (e.g., scheduling operations, access operations, operations initiated by a host processor 210) associated with accessing a corresponding set of one or more memory arrays 250.

In some examples, a logic block 225, a controller 215, or a host interface 216, or a combination thereof may be associated with a “channel set” that corresponds to multiple memory arrays 250 (e.g., for parallel or otherwise coordinated access of the multiple memory arrays 250). For example, such a channel set may be associated with multiple memory arrays 250 accessed via a single interface block 245, or multiple memory arrays 250 each accessed via a respective one of the interface blocks 245, or multiple memory arrays 250 each accessed via a respective one of the interface blocks 220, any of which may be associated with signaling via a single logic block 225, via a single host interface 216, or via a single controller 215. These and other configurations for implementing one or more channel sets in a system may support various techniques for parallelism and high bandwidth data transfer, memory management operations, repair and replacement techniques, or power and thermal distribution, among other techniques that leverage the described coupling of components and interfaces among multiple semiconductor dies (e.g., in accordance with a high bandwidth configuration of the system 200, in accordance with a closely-coupled configuration of the system 200). In some examples, such techniques may be implemented (e.g., at or using a logic block 225) in a manner that is transparent to the host interface 216 or other aspects of a host system 105.

In some examples, a host interface 216 may include a respective set of one or more signal paths for each logic block 225 or interface block 220, such that the host processor 210 may communicate with each logic block 225 or interface block 220 via its corresponding set of signal paths (e.g., in accordance with a selection of the corresponding set to perform access operations via a logic block 225 or interface block 220 that is selected by the host processor 210). Additionally, or alternatively, a host interface 216 may include one or more signal paths that are shared among multiple logic blocks 225 (not shown) or interface blocks 220, and a logic block 225, an interface block 220, or a host processor 210, or any of these may interpret, ignore, respond to, or inhibit response to signaling via shared signal paths of the host interface 216 based on a logical indication (e.g., an addressing indication associated with the logic block 225 or interface block 220, an interface enable signal, or an interface select signal, which may be provided by the host processor 210, the corresponding logic block 225, or the corresponding interface block 220 depending on signaling direction).

In some examples, a host processor 210 may determine to access an address (e.g., a logical address of a memory array 250, a physical address of a memory array 250, an address of a logic block 225, an address of an interface block 220, an address of a host interface 216, in response to an application of or supported by the host processor 210), and determine which controller 215 to transmit access signaling to for accessing the address (e.g., a controller 215, logic block 225, or interface block 220 corresponding to the address). In some examples, the address may be associated with a row of memory cells of the memory array 250, a column of memory cells of the memory array 250, or both. The host processor 210 may transmit access signaling (e.g., one or more access signals, one or more access commands) to the determined controller 215 and, in turn, the determined controller 215 may transmit access signaling to the corresponding logic block 225 or interface block 220 (e.g., in accordance with a command and address protocol). The corresponding interface block 220 may subsequently transmit access signaling to the coupled interface block 245 to access the determined address (e.g., of a corresponding memory array 250).

A die 205 may also include a logic block 230 (e.g., a shared logic block, a central logic block, common logic circuitry, evaluation circuitry, memory system configuration circuitry, memory system management circuitry), which may be configured to communicate (e.g., transmit, receive) signaling with the logic blocks 225, the interface blocks 220, or both of the die 205. In some cases, a logic block 230 may be configured to communicate information (e.g., commands, instructions, indications, data) with one or more logic blocks 225 or interface blocks 220 to facilitate operations of the system 200. For example, a logic block 230 may be configured to transmit configuration signaling (e.g., initialization signaling, evaluation signaling, mapping signaling), which may be received by logic blocks 225 or interface blocks 220 to support configuration of the logic blocks 225 or interface blocks 220, or other aspects of operating the dies 240 (e.g., via the respective interface blocks 245). A logic block 230 may be coupled with each logic block 225 and each interface block 220 via a respective bus 231. In some examples, such buses may each include a respective set of one or more signal paths, such that a logic block 230 may communicate with each logic block 225 or each interface block 220 via the respective set of signal paths. Additionally, or alternatively, such buses may include one or more signal paths that are shared among multiple logic blocks 225 or interface blocks 220 (not shown).

In some implementations, a logic block 230 may be configured to communicate (e.g., transmit, receive) signaling with a host processor 210 or one or more controllers 215 (e.g., via a bus 232, via a contact 212 for a host processor 210 or controller 215 external to a die 205), such that the logic block 230 may support an interface between the host processor 210 or one or more controllers 215 and the logic blocks 225 or interface blocks 220. For example, a host processor 210 or a controller 215 may be configured to transmit initialization signaling (e.g., boot commands), or other configuration or operational signaling, which may be received by a logic block 230 to support initialization, configuration, evaluation, or other operations of the logic blocks 225 or interface blocks 220. Additionally, or alternatively, in some implementations, a logic block 230 may be configured to communicate (e.g., transmit, receive) signaling with a component outside the system 200 (e.g., via a contact 234, which may be an externally-accessible terminal of the die 205), such that the logic block 230 may support an interface that bypasses a host processor 210 or controller 215. Additionally, or alternatively, a logic block 230 may communicate with a host processor 210 or a controller 215, and may communicate with one or more memory arrays 250 of one or more dies 240 (e.g., to perform self-test operations for access of memory arrays 250). In some examples, such implementations may support evaluations, configurations, or other operations of the system 200, via one or more contacts 234 that are accessible at a physical interface of the system, during manufacturing, assembly, validation, or other operation associated with the system 200 (e.g., before coupling with a host processor 210, without implementing a host processor 210, for operations independent of a host processor). Additionally, or alternatively, a logic block 230 may implement one or more aspects of a controller 215. For example, a logic block 230 may include or operate as one or more controllers 215 and may perform operations ascribed to a controller 215.

In some examples, respective signals may be routed between a die 205 die and one or more dies 240. For example, each interface block 220 may be coupled with at least a respective bus 221 of the die 205, and a respective bus 246 of a die 240, that are configured to communicate signaling with a corresponding interface block 245 (e.g., via one or more associated signal paths). For example, the interface block 220-a-1 may be coupled with the interface block 245-a-1 via a bus 221-a-1 and a bus 246-a-1, and the interface block 220-a-2 may be coupled with the interface block 245-a-2 via a bus 221-a-2 and a bus 246-a-2. In some examples, a die 240 may include a bus that bypasses operational circuitry of the die 240 (e.g., that bypasses interface blocks 245 of a given die 240), such as a bus 255. For example, the interface block 220-a-2 may be coupled with the interface block 245-a-2 of the die 240-a-2 via a bus 255-a-1 of the die 240-a-1, which may bypass interface blocks 245 of the die 240-a-1. Such techniques may be extended for interconnection among more than two dies 240 (e.g., for interconnection via a respective bus 255 of multiple dies 240). In some implementations, at least a portion of a bus 221, a bus 246, or a bus 255, or any combination thereof may include one or more conductors in a redistribution layer (RDL) of a respective die (e.g., above or below a semiconductor substrate of the die). Additionally, or alternatively, in some implementations, at least a portion of a bus 221, a bus 246, or a bus 255, or any combination thereof may include one or more vias that are formed through a semiconductor substrate of a respective die (e.g., as one or more through-silicon vias (TSVs)).

The respective signal paths of buses 221, 246, and 255 may be coupled with one another, from one die to another, via various arrangements of contacts at the surfaces of interfacing dies (e.g., exposed contacts, metal surfaces of the respective dies). For example, the bus 221-a-1 may be coupled with the bus 246-a-1 via a contact 222-a-1 of (e.g., at a surface of) the die 205-a and a contact 247-a-1 of the die 240-a-1, the bus 221-a-2 may be coupled with the bus 255-a-1 via a contact 222-a-2 of the die 205 and a contact 256-a-1 of the die 240-a-1, the bus 255-a-1 may be coupled with the bus 246-a-2 via a contact 257-a-1 of the die 240-a-1 and a contact 247-a-2 of the die 240-a-2, and so on. Although each respective bus is illustrated with a single line, coupled via singular contacts, it is to be understood that each signal path of a given bus may be associated with respective contacts to support a separate communicative coupling via each signal path of the given bus. In some examples, a bus 255 may traverse a portion of a die 240 (e.g., in an in-plane direction, along a direction different from a thickness direction, in a waterfall arrangement, in a staircase arrangement), which may support an arrangement of contacts 222 along a surface of a die 205, among other contacts, being coupled with interface blocks 245 of different dies 240 along a stack direction (e.g., via respective contacts 256 and 257 that are non-overlapping when viewed along a thickness direction).

The interconnection of interfacing contacts may be supported by various techniques. For example, in a hybrid bonding implementation, interfacing contacts may be coupled by a fusion of conductive materials (e.g., electrically conductive materials) of the interfacing contacts (e.g., without solder or other intervening material between contacts). For example, in an assembled condition, the coupling of the die 205-a with the die 240-a-1 may include a conductive material of the contact 222-a-2 being fused with a conductive material of the contact 256-a-1, and the coupling of the die 240-a-1 with the die 240-a-2 may include a conductive material of the contact 257-a-1 being fused with a conductive material of the contact 247-a-2, and so on. In some examples, such coupling may include an inoperative fusion of contacts (e.g., a non-communicative coupling, a physical coupling), such as a fusion of the contact 260-a-1 with the contact 256-a-2, neither of which are coupled with operative circuitry of the dies 240-a-1 or 240-a-2. In some examples, such techniques may be implemented to improve coupling strength or uniformity (e.g., implementing contacts 260, which may not be operatively coupled with an interface block 245 or an interface block 220), or such a coupling may be a byproduct of a repetition of components that, in various configurations, may be operative or inoperative. (e.g., where, for dies 240 with a common arrangement of contacts 256 and 257, contacts 256-a-1 and 257-a-1 provide a communicative path between the interface block 245-a-2 and the interface block 220-a-2, but the contacts 256-a-2 and 257-a-2 do not provide a communicative path between an interface block 245 and an interface block 220).

In some examples, a fusion of conductive materials between dies (e.g., between contacts) may be accompanied by a fusion of other materials at one or more surfaces of the interfacing dies. For example, in an assembled condition, the coupling of the die 205-a with the die 240-a-1 may include a dielectric material 207 (e.g., an electrically non-conductive material) of the die 205-a being fused with a dielectric material 242 of the die 240-a-1, and the coupling of the die 240-a-1 with the die 240-a-2 may include a dielectric material 242 of the die 240-a-1 being fused with a dielectric material 242 of the die 240-a-2. In some examples, such dielectric materials may include an oxide, a nitride, a carbide, an oxide-nitride, an oxide-carbide, or other conversion or doping of a substrate material (e.g., a semiconductor substrate material) or other material of the die 205 or dies 240, among other materials that may support such fusion. However, coupling among dies 205 and dies 240 may be implemented in accordance with other techniques, which may implement solder, adhesives, thermal interface materials, and other intervening materials or combinations of materials.

In some examples, dies 240 may be coupled in a stack (e.g., forming a “cube,” a memory stack, or other arrangement of dies 240), and one or more of such stacks may subsequently be coupled with a die 205 (e.g., in a stack-to-chip bonding arrangement). In some examples, respective set(s) of one or more dies 240 may be coupled with each die 205 of multiple dies 205 as formed in a wafer (e.g., in a chip-to-wafer bonding arrangement, in a stack-to-wafer bonding arrangement, before cutting the wafer of dies 205), and the dies 205 of the wafer, each coupled with their respective set(s) of dies 240, may be separated from one another (e.g., by cutting at least the wafer of dies 205, by singulation). In some other examples, respective set(s) of one or more dies 240 may be coupled with a respective die 205 after the die 205 is separated from a wafer of dies 205 (e.g., in a chip-to-chip bonding arrangement). In some other examples, a respective set of one or more wafers, each including multiple dies 240, may be coupled in a stack (e.g., in a wafer-to-wafer bonding arrangement). In various examples, such techniques may be followed by separating stacks of dies 240 from the coupled wafers, or the stack of wafers having dies 240 may be coupled with another wafer including multiple dies 205 (e.g., in a second wafer-to-wafer bonding arrangement), which may be followed by separating systems 200 from the coupled wafers. In some other examples, wafer-to-wafer coupling techniques may be implemented by stacking one or more wafers of dies 240 (e.g., sequentially) over a wafer of dies 205 before separation into systems 200, among other examples for forming systems 200.

The buses 221, 246, and 255 may be implemented to provide a configured signaling (e.g., a coordinated signaling, a logical signaling, modulated signaling, digital signaling) between an interface block 220 and a corresponding interface block 245, which may involve various modulation or encoding techniques by a transmitting interface block (e.g., via a driver component of the transmitting interface block). In some examples, such signaling may be supported by (e.g., accompanied by) clock signaling communicated via the respective buses (e.g., in coordination with signal transmission). For example, the buses may be configured to convey one or more clock signals transmitted by the interface block 220 for reception by the interface block 245 (e.g., to trigger signal reception by a latch or other reception component of the interface block 245, to support clocked operations of the interface block 245). Additionally, or alternatively, the buses may be configured to convey one or more clock signals transmitted by the interface block 245 for reception by the interface block 220 (e.g., to trigger signal reception by a latch or other reception component of the interface block 220, to support clocked operations of the interface block 220). Such clock signals may be associated with the communication (e.g., unidirectional communication, bidirectional communication, deterministic communication) of various signaling, such as control signaling, command signaling, data signaling, or any combination thereof. For example, the buses may include one or more signal paths for communications of a data bus (e.g., one or more data channels, a DQ bus, via a data interface of the interface blocks) in accordance with one or more corresponding clock signals (e.g., data clock signals), or one or more signal paths for communications of a control bus (e.g., a command/address (C/A) bus, via a command interface of the interface blocks) in accordance with one or more clock signals (e.g., control clock signals), or any combination thereof.

Interface blocks 220, interface blocks 245, logic blocks 225, and a logic block 230 each may include circuitry (signaling circuitry, multiplexing circuitry, processing circuitry, controller circuitry, logic circuitry, physical components, hardware) in various configurations (e.g., hardware configurations, logic configurations, software or instruction configurations) that support the functionality allocated to the respective block for accessing or otherwise operating a corresponding set of memory arrays 250. For example, interface blocks 220 may include circuitry configured to perform a first subset of operations that support access of the memory arrays 250, and interface blocks 245 may include circuitry configured to perform a second subset of operations that support access of the memory arrays 250. In some examples, the interface blocks 220, the interface blocks 245, and logic blocks 225 may support a functional split or distribution of functionality associated with a memory system controller 140, a local controller 150, or both across multiple dies (e.g., a die 205 and at least one die 240). In some implementations, a logic block 230 may be configured to coordinate or configure aspects of the operations of the interface blocks 220, of the interface blocks 245, of the logic blocks 225, or a combination thereof, and may support implementing one or more aspects of a memory system controller 140. Such operations, or subsets of operations, may include operations performed in response to commands from the host processor 210 or a controller 215, or operations performed without commands from a host processor 210 or a controller 215 (e.g., operations determined by or initiated by a logic block 225, operations determined by or initiated by an interface block 220, operations determined by or initiated by an interface block 245, operations determined by or initiated by a logic block 230), or various combinations thereof.

In some implementations, the system 200 may include one or more instances of non-volatile storage (e.g., non-volatile storage 235 of a die 205, non-volatile storage 270 of one or more dies 240, or a combination thereof). In some examples, a logic block 230, logic blocks 225, interface blocks 220, interface blocks 245, or a combination thereof may be configured to communicate signaling with one or more instances of non-volatile storage. For example, a logic block 230, logic blocks 225, interface blocks 220, or interface blocks 245 may be coupled with one or more instances of non-volatile storage via one or more buses (not shown), or respective contacts (not shown), where applicable, which may each include one or more signal paths operable to communicate signaling (e.g., command signaling, data signaling). In some examples, a logic block 230, one or more logic blocks 225, one or more interface blocks 220, one or more interface blocks 245, or a combination thereof may configure one or more operations based on information (e.g., instructions, configurations, parameters) stored in one or more instances of non-volatile storage. Additionally, or alternatively, in some examples, a logic block 230, one or more logic blocks 225, one or more interface blocks 220, one or more interface blocks 245, or a combination thereof may write information (e.g., configuration information, evaluation information) to be stored in one or more instances of non-volatile storage. In some examples, such non-volatile storage may include fuses, antifuses, or other types of one-time programmable storage elements, or any combination thereof.

In some implementations, the system 200 may include one or more sensors (e.g., one or more sensors 237 of a die 205, one or more sensors 275 of one or more dies 240, or a combination thereof). In some implementations, a logic block 230, logic blocks 225, interface blocks 220, interface blocks 245, or a combination thereof may be configured to receive one or more indications based on measurements of one or more sensors of the system 200. For example, a logic block 230, logic blocks 225, interface blocks 220, or interface blocks 245 may be coupled with one or more sensors via one or more buses (not shown), or respective contacts (not shown). Such sensors may include temperature sensors, current sensors, voltage sensors, counters, and other types of sensors. In some examples, a logic block 230, one or more logic blocks 225, one or more interface blocks 220, one or more interface blocks 245, or a combination thereof may configure one or more operations based on output of the one or more sensors. For example, a logic block 230 may configure one or more operations of logic blocks 225 or interface blocks 220 based on signaling (e.g., indications, data) received from the one or more sensors. Additionally, or alternatively, a logic block 225 or an interface block 220 may generate access signaling for transmitting to a corresponding interface block 245 based on one or more sensors.

In some examples, circuitry of logic blocks 225, interface blocks 220, interface blocks 245, or a logic block 230, or any combination thereof may include components (e.g., transistors) formed at least in part from doped portions of a substrate of the respective die. In some examples, a substrate of a die 205 may have characteristics (e.g., materials, material characteristics, physical shapes or dimensions) that are different from those of a substrate of a die 240. Additionally, or alternatively, in some examples, transistors formed from a substrate of a die 205 may have characteristics (e.g., manufacturing characteristics, performance characteristics, physical shapes or dimensions) that are different from transistors formed from a substrate of a die 240 (e.g., in accordance with different transistor architectures, in accordance with different transistor designs).

In some examples, the interface blocks 220 may support a layout for one or more components within the interface blocks 220. For example, the layout may include pairing components to share an access port (e.g., a command port, a data port). Further, in some examples, the layout may support interfaces for a controller 215 (e.g., a host interface 216) that are different from interfaces for an interface block 245 (e.g., via the buses 221). For instance, a host interface 216 may be synchronous and have separate channels for read and write operations, while an interface between an interface block 220 and one or more interface blocks 245 may be asynchronous and support both read and write operations with the same channel. In some examples, signaling of a host interface 216 may be implemented with a deterministic timing (e.g., deterministic between a controller 215 and a logic block 225 or one or more interface blocks 220), which may be associated with a configured timing between a first signal and a responsive second signal. In some examples, signaling between an interface block 220 and one or more interface blocks 245 may be implemented with a timing that is different from timing of a host interface 216 (e.g., in accordance with a different clock frequency, in accordance with a timing offset, such as a phase offset), which may be deterministic or non-deterministic.

A die 240 may include one or more units 265 (e.g., modules) that are separated from a semiconductor wafer having a pattern (e.g., a two-dimensional pattern) of units 265. Although each die 240 of the system 200 is illustrated with a single unit 265 (e.g., unit 265-a-1 of die 240-a-1, unit 265-a-2 of die 240-a-2), a die 240 in accordance with the described techniques may include any quantity of units 265, which may be arranged in various patterns (e.g., sets of one or more units 265 along a row direction, sets of one or more units 265 along a column direction, among other patterns). Each unit 265 may include at least the circuitry of a respective interface block 245, along with memory array(s) 250, a bus 251, a bus 246, and one or more contacts 247 corresponding to the respective interface block 245. In some examples, where applicable, each unit 265 may also include one or more buses 255, contacts 256, contacts 257, or contacts 260 (e.g., associated with a respective interface block 245 of a unit 265 of a different die 240), which may support various degrees of stackability or modularity among or via units 265 of other dies 240. Although examples of non-volatile storage 270 and sensors 275 are illustrated outside units 265, in some other examples, non-volatile storage 270, sensors 275, or both may additionally, or alternatively, be included in units 265.

In some examples, the interface blocks 220 may include circuitry configured to receive first access command signaling (e.g., from a host processor 210, from a controller 215, from a logic block 225, via a host interface 216, via one or more contacts 212 from a host processor 210 or controller 215 external to a die 205, based on a request from a host application), and to transmit second access command signaling to the respective (e.g., coupled) interface block 245 based on (e.g., in response to) the received first access command signaling. The interface blocks 245 may accordingly include circuitry configured to receive the second access command signaling from the respective interface block 220 and, in some examples, to access a respective set of one or more memory arrays 250 based on (e.g., in response to) the received second access command signaling. In various examples, the first access command signaling may include access commands that are associated with a type of operation (e.g., a read operation, a write operation, a refresh operation, a memory management operation), which may be associated with an indication of an address of the one or more memory arrays 250 (e.g., a logical address, a physical address). In some examples, the first access command signaling may include an indication of a logical address associated with the memory arrays 250, and circuitry of an interface block 220 may be configured to generate the second access command signaling to indicate a physical address associated with the memory arrays 250 (e.g., a row address, a column address, using a logical-to-physical (L2P) table or other mapping or calculation functionality of the interface block 220).

In some examples, to support write operations of the system 200, circuitry of the interface blocks 220 may be configured to receive (e.g., from a host processor 210, from a controller 215, from a logic block 225) first data signaling associated with the first access command signaling, and to transmit second data signaling (e.g., associated with second access command signaling) based on received first access command signaling and first data signaling. The interface blocks 245 may accordingly be configured to receive second data signaling, and to write data to one or more memory arrays 250 (e.g., in accordance with an indicated address associated with the first access command signaling) based on the received second access command signaling and second data signaling. In some examples, the interface blocks 220 may include an error control functionality (e.g., error detection circuitry, error correction circuitry, error correction code (ECC) logic, an ECC engine) that supports the interface blocks 220 generating the second data signaling based on performing an error control operation using the received first data signaling (e.g., detecting or correcting an error in the first data signaling, determining one or more parity bits to be conveyed in the second data signaling and written with the data).

In some examples, to support read operations of the system 200, circuitry of the interface blocks 245 may be configured to read data from the memory arrays 250 based on received second access command signaling, and to transmit first data signaling based on the read data. The interface blocks 220 may accordingly be configured to receive first data signaling, and to transmit second data signaling (e.g., to a host processor 210, to a controller 215, to a logic block 225) based on the received first data signaling. In some examples, the interface blocks 220 may include an error control functionality that supports the interface blocks 220 generating the second data signaling based on performing an error control operation using the received first data signaling (e.g., detecting or correcting an error in the first data signaling, which may include a calculation involving one or more parity bits received with the first data signaling).

In some examples, access command signaling that is transmitted to the interface blocks 245, among other signaling, may be generated (e.g., based on access command signaling received from a host processor 210, based on initiation signaling received from a host processor 210, without receiving or otherwise independent from signaling from a host processor 210) in accordance with various determination or generation techniques configured at the interface blocks 220 or the logic blocks 225 (e.g., based on a configuration for accessing memory arrays 250 that is modified at the interface blocks 220 or the logic blocks 225). In some examples, such techniques may involve signaling or other coordination with a logic block 230, a logic block 225, a host processor 210, one or more controllers 215, one or more instances of non-volatile storage, one or more sensors, or any combination thereof. Such techniques may support the interface blocks 220 or logic blocks 225 configuring aspects of the access operations performed on the memory arrays 250 by a respective interface block 245, among other operations. For example, interface blocks 220 or logic blocks 225 may include evaluation circuitry, access configuration circuitry, signaling circuitry, scheduling circuitry, repair circuitry, refresh circuitry, error control circuitry, adverse access (e.g., row hammer) mitigation circuitry, and other circuitry operable to configure operations associated with one or more dies (e.g., operations associated with accessing memory arrays 250 of the dies 240).

In some examples, functionality of a die 205 may be implemented as a semiconductor unit (e.g., a semiconductor system) that is formed with multiple semiconductor die portions (e.g., semiconductor chiplets, relatively smaller semiconductor dies), and each die portion may include respective portions of circuitry associated with the die 205. For example, a unit 280 may represent a portion of the circuitry components included in a die portion (e.g., in a chiplet), and the die portion may include an integer multiple of units 280. In some examples, each semiconductor die portion of a semiconductor unit may include different respective portions of circuitry. As a non-limiting example, a semiconductor unit (e.g., having the functionality of a die 205) may be formed by one or more first die portions having one or more units 280-a-1 and one or more second die portions having one or more units 280-a-2. The one or more units 280-a-1 may include one or more interface blocks 220, a logic block 225, or any combination thereof, and the one or more units 280-a-2 may include a host processor 210, one or more controllers 215, a logic block 230, or any combination thereof.

Semiconductor dies (e.g., DRAM dies, dies 240, dies 205) associated with a system 200 may be bonded via various techniques. However, some manufacturing operations performed during device production may produce debris (e.g., debris particles), which may collect on one or more respective surfaces of semiconductor dies prior to bonding the dies. A collection of debris or other foreign particles may adversely affect electrical characteristics of one or more of the bonded dies (e.g., by inhibiting one or more electrical connections between the bonded dies), which may cause a system 200 to be rejected and discarded. Some cleaning operations may be utilized to remove at least some debris. However, such cleaning operations may, in some cases, cause damage (e.g., breakage) to a die surface, may not sufficiently clean the particles from the surface, or may be associated with other deficiencies. For example, in some bonding schemes (e.g., C2W hybrid bonding), particle cleaning and management to maintain particles below a threshold (e.g., under a threshold quantity of particles at 0.2 micrometers) may be challenging to achieve (e.g., in terms of cleaning and tool readiness).

In accordance with one or more techniques described herein, a semiconductor device (e.g., a system 200 or a component thereof) may be manufactured using various operations (e.g., bonding techniques) improve reliability of the semiconductor device. Such operations may include wafer reconstruction operations (e.g., reconstruction of KGDs, reconstruction of known-good dies 240 to form a reconstructed wafer of dies 240), planarizing operations (e.g., CMP), and bonding operations (e.g., W2W bonding, C2W bonding, S2W bonding). For example, particles may be removed via CMP to polish a wafer surface and remove a majority (if not all) of the particles on the wafer surface. In some examples, a CMP tool may provide a relatively low particle defect level (e.g., with a majority of the particles having a size less than 100 nanometers), and a reconstructed wafer of dies 240 may leverage a wafer level CMP tool for surface refreshing. Additionally, or alternatively, a light CMP may be used as a die level CMP tool for surface refreshing, which may remove an amount of debris that satisfies or exceeds a threshold (e.g., greater than 99 percent particle removal).

By utilizing such CMP and other operations (e.g., C2W hybrid bonding schemes described herein), a semiconductor device (e.g., for 3-dimensional stack, such as the system 200, HBM) may be more-easily fabricated. Accordingly, techniques are described to introduce such aspects (e.g., various options of C2W hybrid bonding process flows) into a manufacturing procedure and may result in structural differences in a final device package. In some examples, a first set of memory array dies (e.g., dies 240) may be bonded to a carrier to form a reconstructed wafer (e.g., after covering the memory dies with one or more dielectric materials), which may be planarized (e.g., and polished) before bonding (e.g., which may also remove debris particles). Subsequently, one or more additional sets of memory array dies may be bonded to the first set of memory array dies to form a stack of memory array dies of a semiconductor device.

The additional sets of memory array dies may be bonded with the first set after being formed as a reconstructed wafer (e.g., one or more second dielectric materials may be formed around the additional dies before bonding, via W2W bonding), or each die may be individually bonded to a respective die of the first set (e.g., one or more second dielectric materials may be formed around the additional dies after bonding, via C2W bonding). The stack of memory array dies may be bonded with a logic wafer (e.g., a die 205), and one or more molding compounds may be formed over the stack of memory dies and the logic wafer. Thus, by utilizing one or more techniques herein, a system 200 may be manufactured with increased reliability (e.g., based on reduced particle collection), increased structural integrity, and improved device yield, among other benefits.

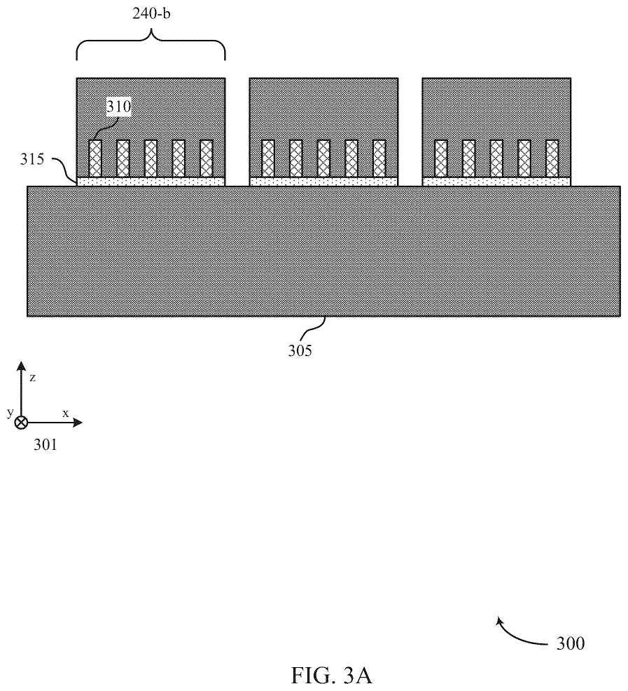

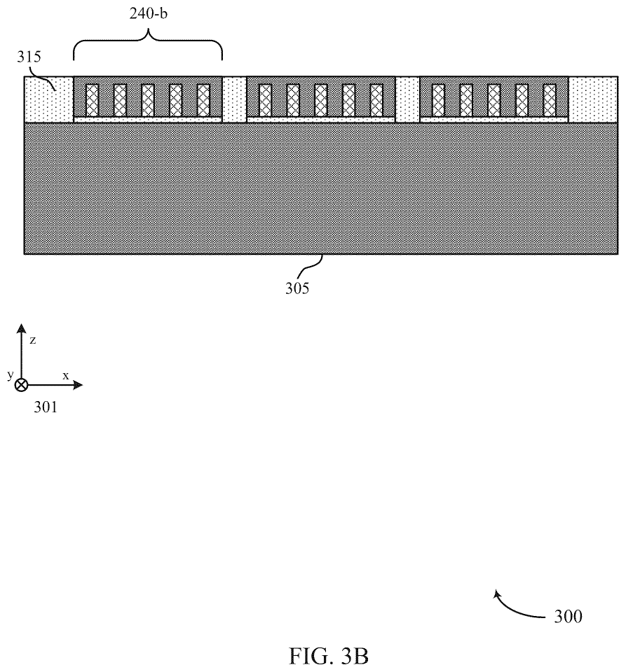

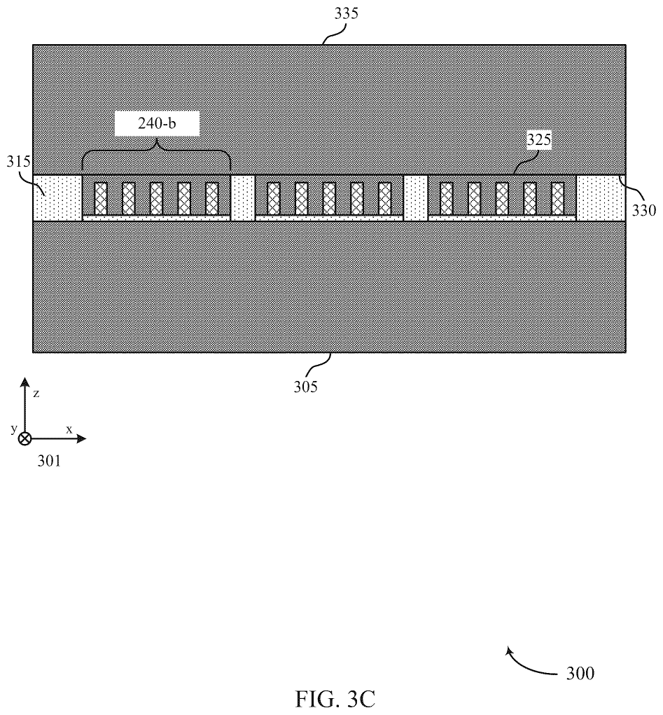

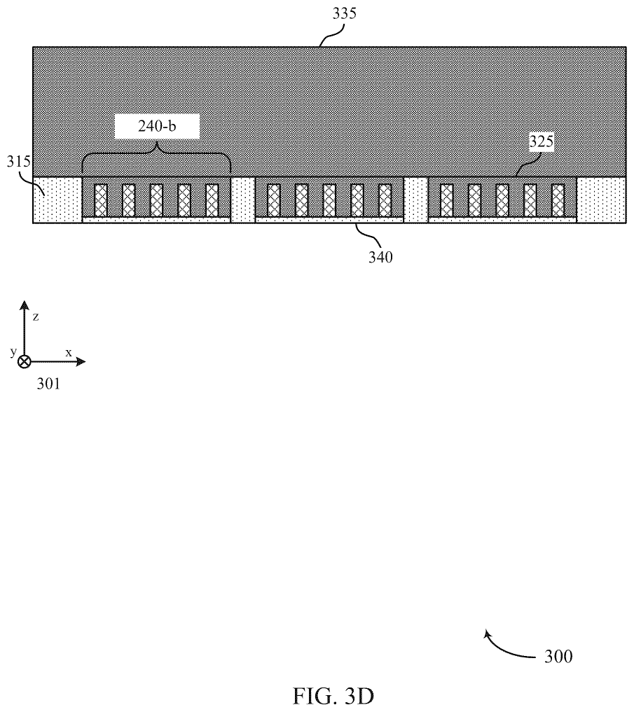

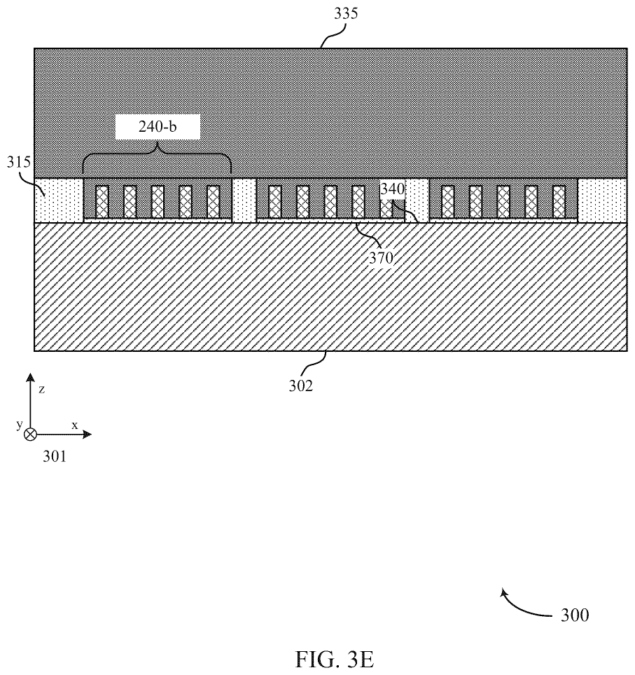

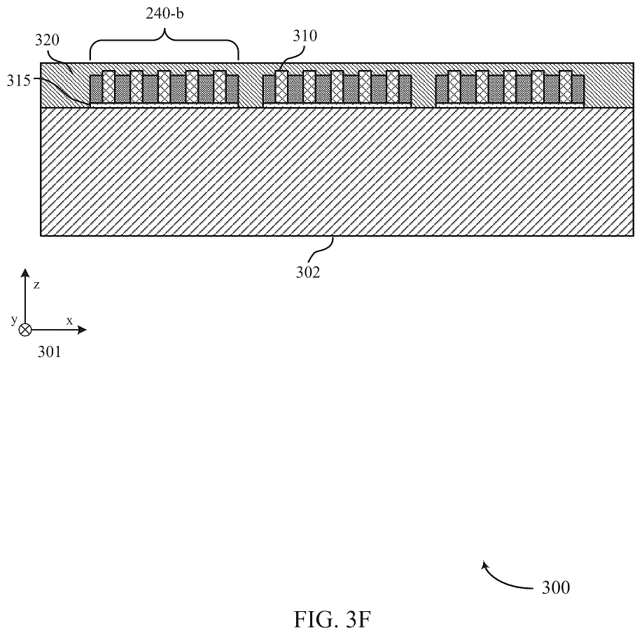

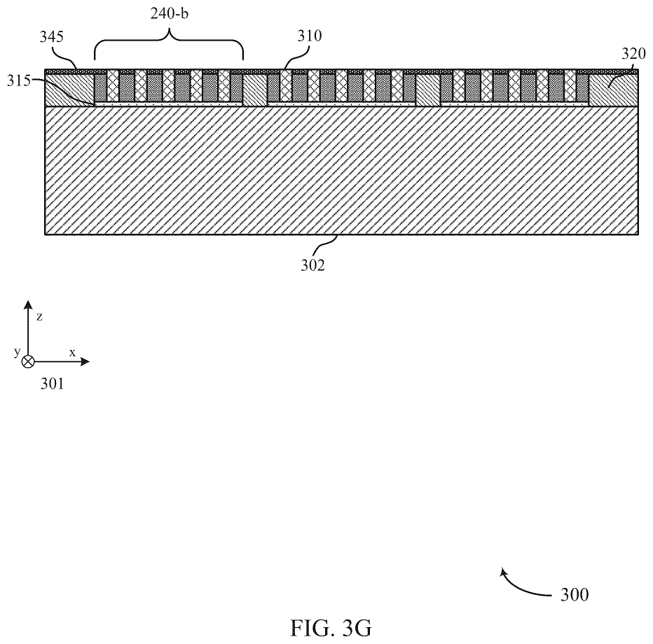

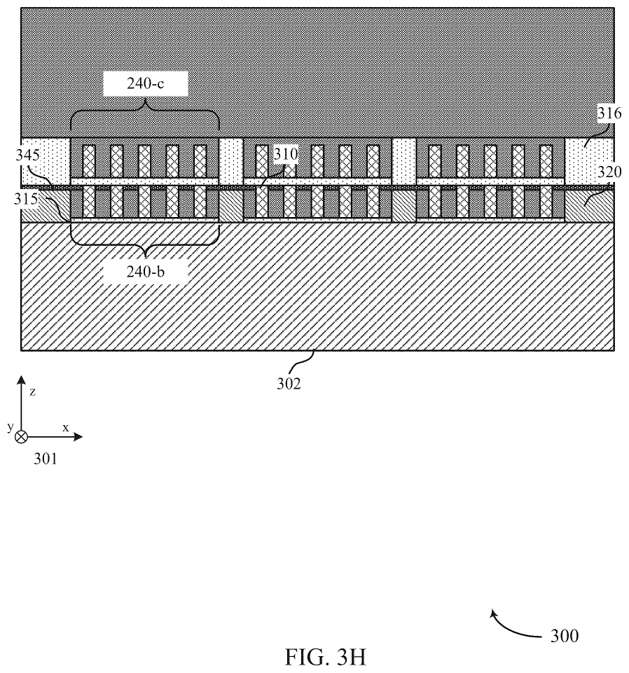

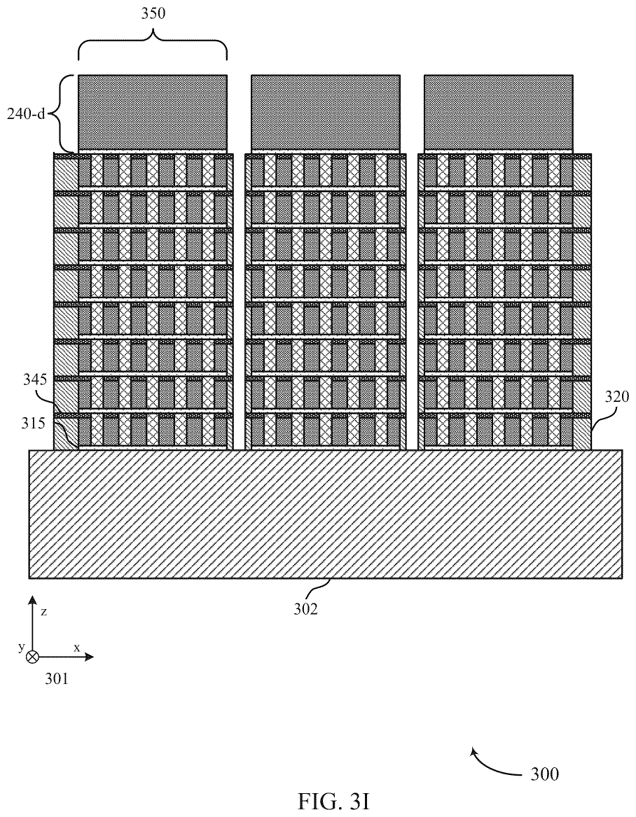

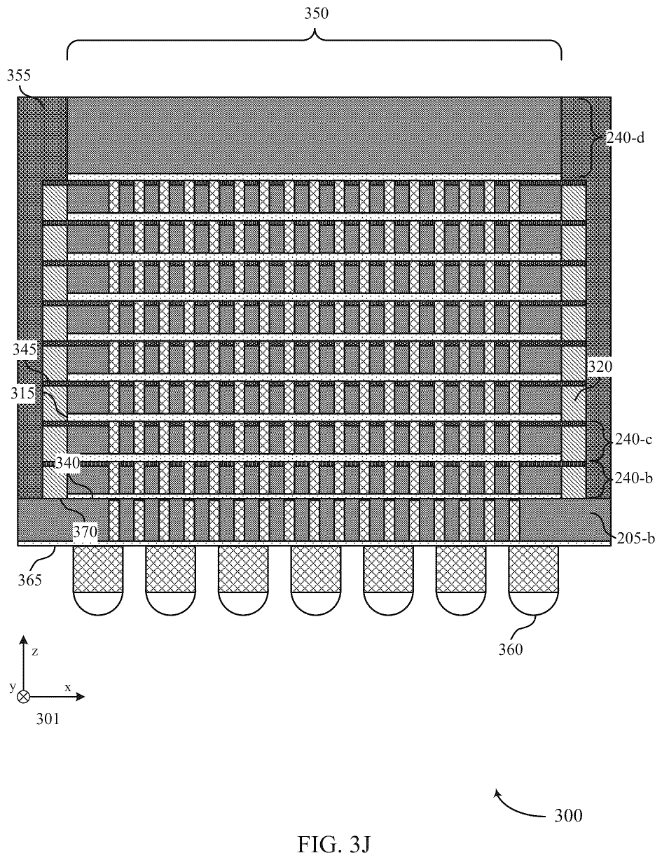

FIGS. 3A through 3J illustrate examples of operations that support hybrid bonding techniques for stacked semiconductor systems in accordance with examples as disclosed herein. Operations are illustrated with reference to a device 300, which may be an example of or include an electronic device (e.g., a semiconductor device, a system 100, a memory system 110, a host system 105, a system 200). For example, FIGS. 3A through 3J may illustrate aspects of a first sequence of operations that support manufacturing a system 100 or a portion thereof, a system 200 or a portion thereof, or some other device. Each of the figures may be described with reference to an x-direction, a y-direction, and a z-direction of a coordinate system 301. Operations illustrated in and described with reference to FIGS. 3A through 3J may be performed by a manufacturing system, such as a semiconductor fabrication system configured to perform additive operations (e.g., deposition, epitaxy, bonding), subtractive operations (e.g., etching, trenching, planarizing, polishing, grinding, scraping), modifying operations (e.g., oxidizing, doping, reacting, converting), and supporting operations (e.g., masking, patterning, photolithography, aligning), among other operations that support the described techniques.

In some examples, portions of the device 300 that are illustrated with a same fill pattern may be formed of same or similar materials and portions that are illustrated with different patterns may be formed of different materials. Various dielectric materials are described herein. Each dielectric material may include a silicon oxide, silicon nitride, a silicon carbon nitride, a tetraethyl orthosilicate (TEOS), some other dielectric material, or any combination thereof. Additionally, conductive materials described herein may include copper, aluminum, tungsten, titanium, some other conductive material, or any combination thereof. In some examples, the mold compound materials described herein may include epoxy-based materials (e.g., epoxy resin, thermoset materials, organic materials).

FIG. 3A shows an example of a cross-sectional view of the device 300 after a first set of one or more fabrication operations. For example, the first operations may include bonding a set of one or more dies 240-b (e.g., memory array dies, bottom dies) to a carrier 305 (e.g., a semiconductor material carrier, a silicon carrier). Each die 240-b may include a respective substrate (e.g., substrate material, semiconductor substrate, semiconductor substrate portion) and may include (e.g., be formed with) one or more vias 310 (e.g., TSVs) formed of one or more conductive materials (e.g., one or more cavities filled with conductive material). Semiconductor substrate materials described herein may include memory array circuitry, interconnection circuitry, or other circuitry. Each die 240-b may include a dielectric material 315, which may facilitate a bond (e.g., a fusion bond) with a surface of the carrier 305 (e.g., a dielectric material of the carrier, not shown). The carrier may also be formed of a substrate material (e.g., a semiconductor material, a silicon substrate, a sacrificial substrate).

FIG. 3B shows an example of a cross-sectional view of the device 300 after a second set of one or more fabrication operations. For example, the second operations may include thinning of a respective substrate of each die 240-b. The second operations may also include forming a dielectric material 315 (e.g., gap filling) between and over the set of dies 240-b (e.g., which may include a dual damascene process that forms material a multiple depths). Subsequently, the second operations may also include planarizing (e.g., CMP, cleaning) the dielectric material 315 (e.g., to be coplanar with the respective substrates of the dies 240-b), and subsequent bonding operations may be based on the planarizing.

FIG. 3C shows an example of a cross-sectional view of the device 300 after a third set of one or more fabrication operations. For example, the third operations may include bonding (e.g., W2W fusion bonding) a respective surface 325 of the set of dies 240-b to a surface 330 of a carrier 335. The set of dies 240-b may be coupled with the dielectric material 315, which may extend along a direction (e.g., an x direction) from respective semiconductor substrate portions of each of the dies 240-b.

FIG. 3D shows an example of a cross-sectional view of the device 300 after a fourth set of one or more fabrication operations. For example, the fourth operations may include removing the carrier 305 to expose a surface 340 of the set of dies 240-b. The fourth operations may also include planarizing (e.g., CMP, cleaning) at least a portion of the dielectric material 315 (e.g., at the surface 340).

FIG. 3E shows an example of a cross-sectional view of the device 300 after a fifth set of one or more fabrication operations. For example, the fifth operations may include bonding (e.g., W2W bonding) the surface 340 of the set of dies 240-b to a wafer 302 (e.g., to a surface 370 of the wafer 302), which may include multiple logic dies 205 (e.g., prior to singulation from the wafer 302, as a wafer reconstruction of singulated logic dies 205). The bonding may be based on bonding a first conductive material at the surface 340 (e.g., associated with contacts 247 or 256) with a second conductive material of the wafer 302 (e.g., associated with contacts 222), and on bonding the dielectric material 315 (e.g., an example of a dielectric material 242) with a second dielectric material (e.g., an example of a dielectric material 207) of the wafer 302. In some examples, the surface 340 may be a front side of the set of dies 240-b and the surface 370 may be a front side of the wafer 302. That is, bonding the set of dies 240-b to the wafer 302 may be a front-to-front bonding.

FIG. 3F shows an example of a cross-sectional view of the device 300 after a sixth set of one or more fabrication operations. For example, the sixth operations may include removing (e.g., thinning) the carrier 335 to expose or remove material past the surface 325 of the set of dies 240-b. The sixth operations may also include removing a portion of the respective semiconductor substrate portions (e.g., silicon etching) of each die 240-b to expose (e.g., reveal) one or more vias 310, or cavities, of the surface 325. The sixth operations may also include forming (e.g., depositing, after removing the carrier 335) a dielectric material 320 between and over the set of dies 240-b and over the wafer 302 of logic dies 205. In some examples, the dielectric material 320 may replace at least a portion of dielectric material 315 that was removed (e.g., which may include a dual damascene process that forms material a multiple depths).

FIG. 3G shows an example of a cross-sectional view of the device 300 after a seventh set of one or more fabrication. For example, the seventh operations may include planarizing the dielectric material 320 to reveal or planarize vias 310 (e.g., TSVs, as a CMP and TSV reveal). The seventh operations may also include forming (e.g., as part of a dual damascene process, after removing the portion the respective semiconductor substrate portions of the dies 240-b) a conductive material in one or more first cavities formed at a first depth in the surface 325 and in one or more second cavities formed at a second depth in the surface 325. In some examples, bonding the dies 240-b with other dies 240 may be based on forming the conductive material. In some examples, the one or more first cavities may be associated with one or more bonding pads (e.g., hybrid bonding pads. contacts 257, contacts 260), and the one or more second cavities may be associated with one or more vias coupled with the one or more bonding pads and with the vias 310, which may be coupled with circuitry of the respective semiconductor substrate portions of the dies 240-b. The seventh operations may also include forming a dielectric material 345 over the dielectric material 320 and the substrate portions of the dies 240-b. In some examples, forming the dielectric material 345 may also be formed using a dual damascene process (e.g., forming material at multiple depths).

FIG. 3H shows an example of a cross-sectional view of the device 300 after an eighth set of one or more fabrication operations. For example, the eighth operations may include bonding (e.g., W2W bonding of reconstructed wafers) a set of dies 240-c (e.g., another layer of dies 240) to an exposed surface of the set of dies 240-b based on bonding a conductive material at the surface (e.g., associated with contacts 257 or 260) to a conductive material of the set of one or more second dies 240-c (e.g., associated with contacts 247 or 256), and on bonding the dielectric material 345 with a dielectric material 316 of the set of dies 240-c. In some examples, bonding the dies 240-c may be based on one or more bonding pads. In some examples, bonding the set of dies 240-c to the set of dies 240-b may be a back-to-front bonding. That is, a frontside of the set of dies 240-c may be bonded with a backside (e.g., the exposed surface) of the set of dies 240-b.

FIG. 3I shows an example of a cross-sectional view of the device 300 after a ninth set of one or more fabrication operations. For example, the ninth operations may include repeating the operations of FIGS. 3F through 3H (or other techniques described herein) to stack multiple layers of dies 240, where each layer or each set of dies 240 (e.g., except for a set of dies 240-d, top dies) may be respectively associated with a dielectric material 315, a dielectric material 320, and a dielectric material 345. In some examples, at least some of the dies 240 (e.g., all dies 240 of the stack except dies 240-d) may be bonded in accordance with a W2W bonding (e.g., bonding wafers of dies 240, such as wafers of dies 240-b, 240-c), and some other dies 240 (e.g., the dies 240-d, the top dies) may be bonded in accordance with a C2W bonding. In some examples, a set of dies 240-d (e.g., top dies in the stack) may be relatively thicker than other dies 240 (e.g., to achieve a desired overall thickness along the z-direction, to improve structural integrity). In some examples, the ninth operations may also include removing (e.g., dielectric cutting, laser groove, dicing, singulation) a portion of the dielectric materials 315, the dielectric materials 320, and the dielectric materials 345 from each layer of a stack 350. Based on the removal of dielectric materials, a stack 350 (e.g., a bonded set) of at least one first memory array die and at least one second memory array die (e.g., a stack of memory dies 240) may be separated (e.g., isolated, singulated) from other stacks 350 of memory array dies (e.g., to form respective systems 200).

FIG. 3J shows an example of a cross-sectional view of a device 300 after a tenth set of one or more fabrication operations. For example, the tenth operations may include forming, after removing the dielectric materials (e.g., after stack singulation), a mold compound 355 over a stack 350 of the set of dies 240 (e.g., including the dies 240-b, dies 240-c, and other dies in the stack), a logic die 205-b of the wafer 302, and the set of one or more second memory array dies. In some examples, the tenth operations may also include forming one or more conductive contacts 360 (e.g., including a solder material portion and a conductive pillar portion, among other configurations) on a surface 365 of the die 205-b opposite a surface 370 of the die 205-b that is bonded with the surface 340 of the set of dies 240-b.

Thus, based on the manufacturing operations described herein, a device 300 (e.g., one or more systems 200 from a device 300) may be fabricated to include a stack 350 of dies 240, where each die 240 of the stack 350 is bonded with at least one other die 240 in the stack 350. The device 300 may include first dielectric material portions (e.g., dielectric materials 320), and each of the first dielectric material portions may extend along a direction (e.g., an x direction) beyond a lateral boundary of the stack 350 and from a respective semiconductor substrate portion of a die 240. In some examples, at least some of the dies 240 in the stack 450 (e.g., die 240-b, die 240-c) may have one or more surfaces (e.g., side surfaces, lateral surfaces) that are in contact with respective first dielectric material portions (e.g., dielectric materials 320). The device 300 may include a logic die 205-b bonded with a die 240-a of the stack 350. In some examples, the logic die 205-b may include circuitry operable to facilitate one or more access operations of the dies 240 of the stack 350. In some examples, the device 300 may include a mold compound 355 formed over the stack 350 of dies 240, the dielectric material portions, and the logic die 205-b. In some examples, lateral surfaces (e.g., side surfaces) of the die 240-d (e.g., a top die) may be in contact with the mold compound 355 and may not be in contact with the first dielectric material portions (e.g., the dielectric materials 320). Further, the lateral surfaces of other dies 240 (e.g., die 240-b, die 240-c) may be in contact with the first dielectric material portions, and the dielectric material portions may be in contact with the mold compound 355.

In some examples, the device 300 may include second dielectric material portions (e.g., dielectric material 315), and each of the second dielectric material portions may extend along the direction between a first lateral boundary of a respective die 240 and a second lateral boundary of the respective die 240. In some examples, the device 300 may include third dielectric material portions (e.g., dielectric material 345), and each of the third dielectric material portions may be formed over a respective die 240 and extend along the direction between a first lateral boundary of a respective first dielectric material portions of a respective die 240 and a second lateral boundary the respective first dielectric material portion. In some examples, respective dielectric materials 345 may enclose a respective dielectric material 320 (e.g., a gap fill layer) on two sides.

In some examples, a bonding of each die 240 of the stack 350 with at least one other die 240 may include a first bonding between respective conductive materials and second bonding between respective dielectric materials of each die 240. In some examples, the dies 240 of the stack 350 may be bonded in accordance with a front-to-back bonding, and the first die 240-a may be bonded with the logic die 205-b in accordance with a front-to-front bonding. The device 300 may include any quantity of dies 240 including more or fewer dies 240 than shown (e.g., four dies 240, eight dies 240, sixteen dies 240, or some other integer quantity of dies 240).

Accordingly, by implementing one or more techniques herein, a device 300 (e.g., a semiconductor device, one or more systems 200 from a device 300) may be manufactured with increased reliability (e.g., based on reduced particle collection, based on CMP-based particle removal), increased structural integrity, and improved device yield. For example, the described techniques may more-effectively remove (e.g., or otherwise reduce) debris particles during the manufacturing process, thus improving a likelihood of forming reliable electrical connections (e.g., bonds) between respective dies 240 and dies 205. Additionally, by implementing the described techniques, relatively fewer devices may be rejected during fabrication, which may result in reduced electronic waste and extended the life of electronic devices, among other benefits.

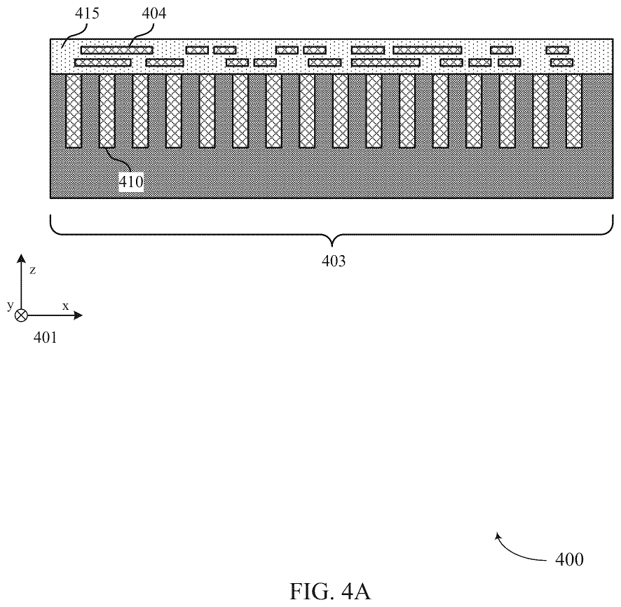

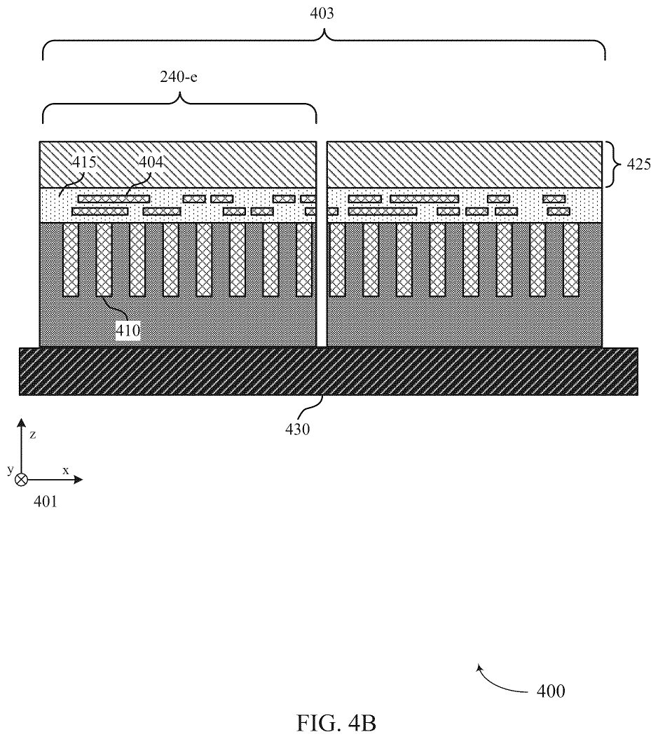

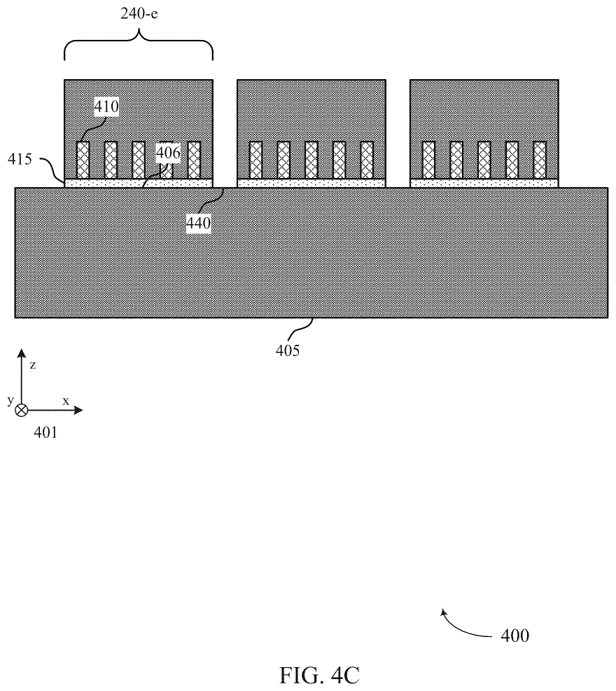

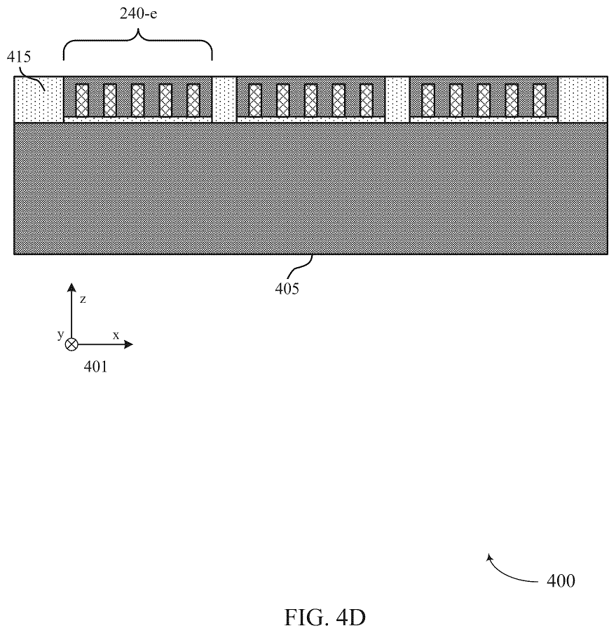

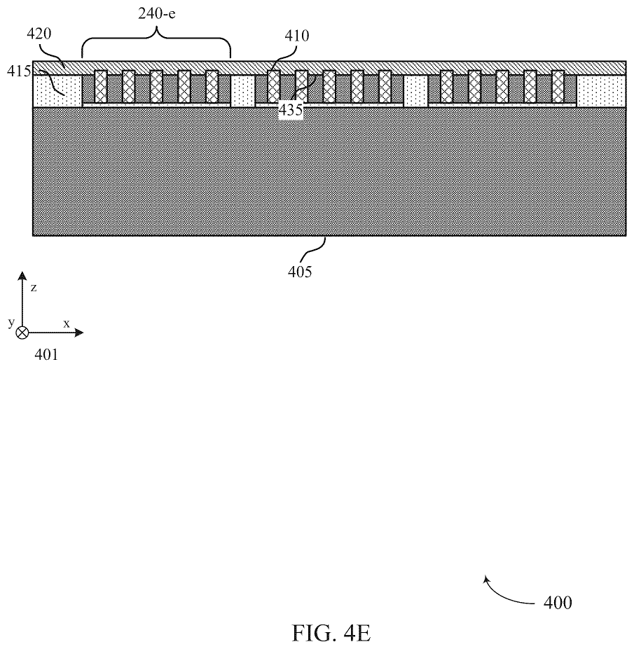

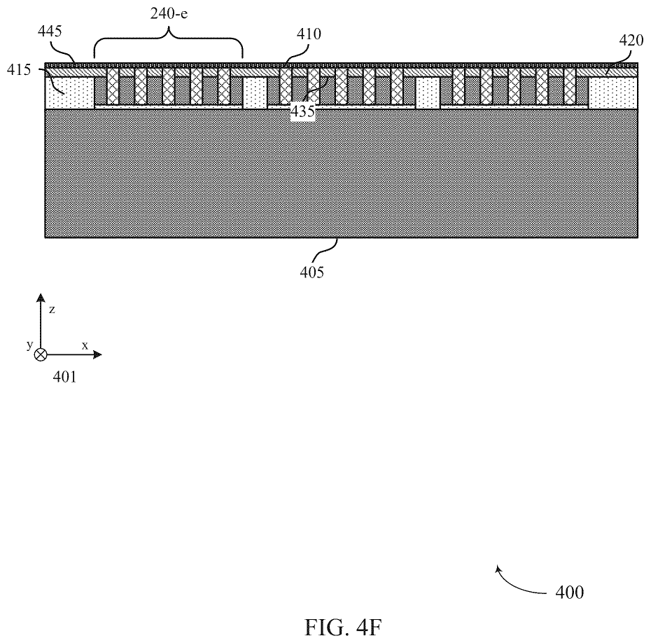

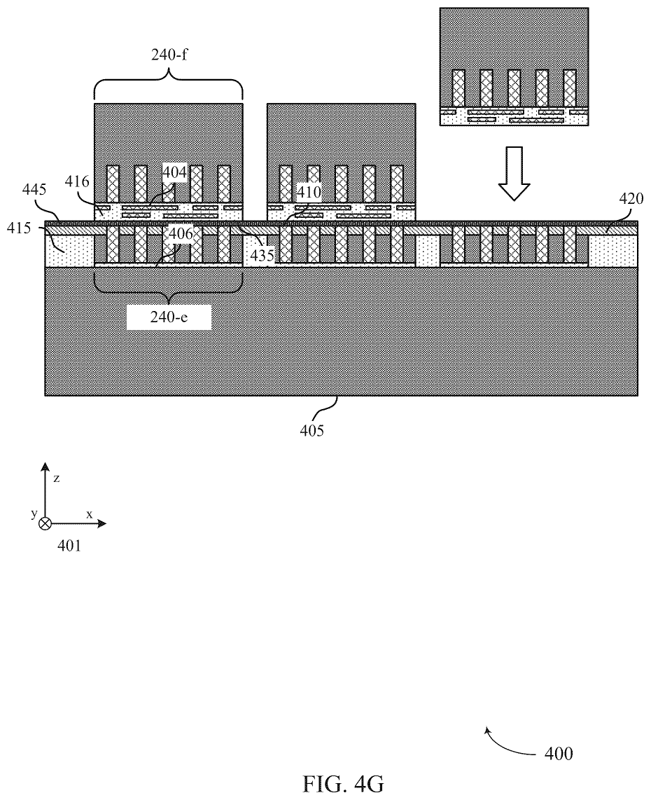

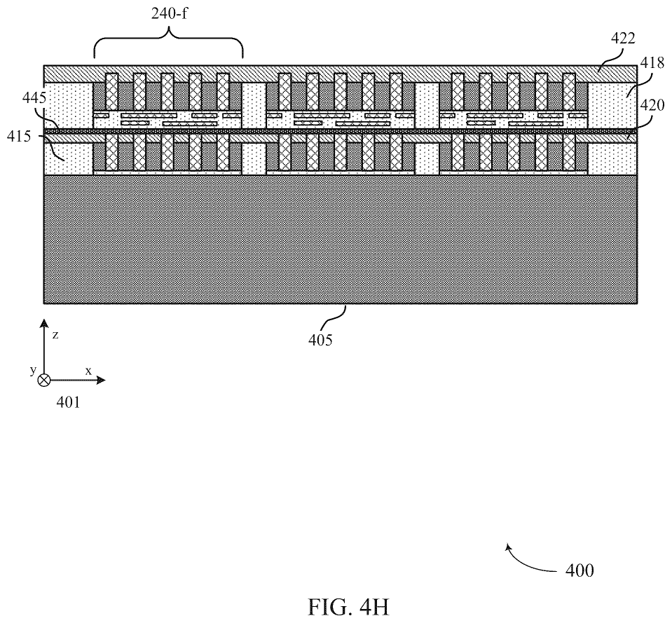

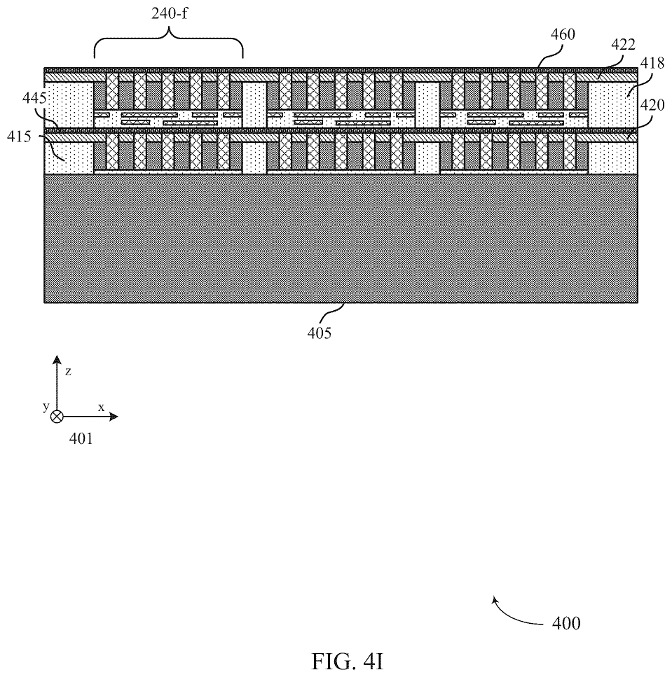

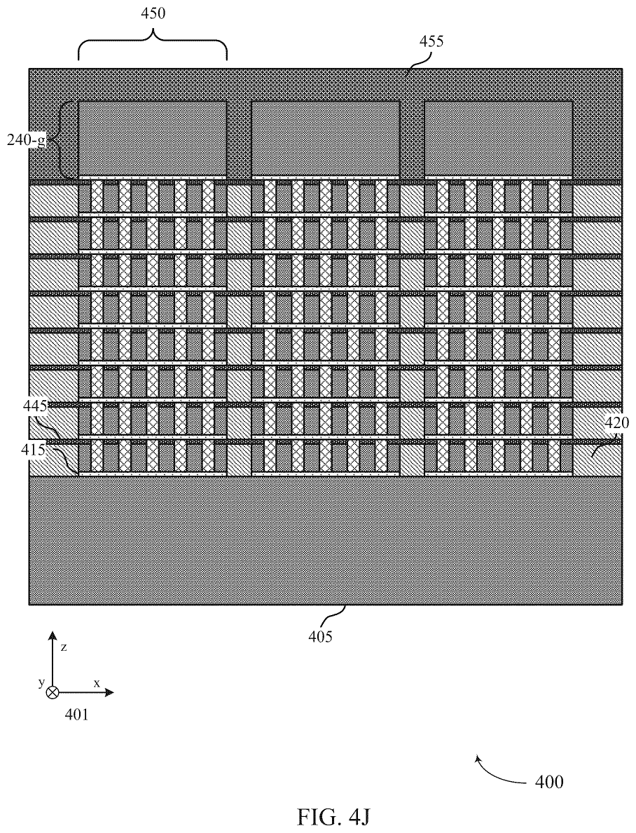

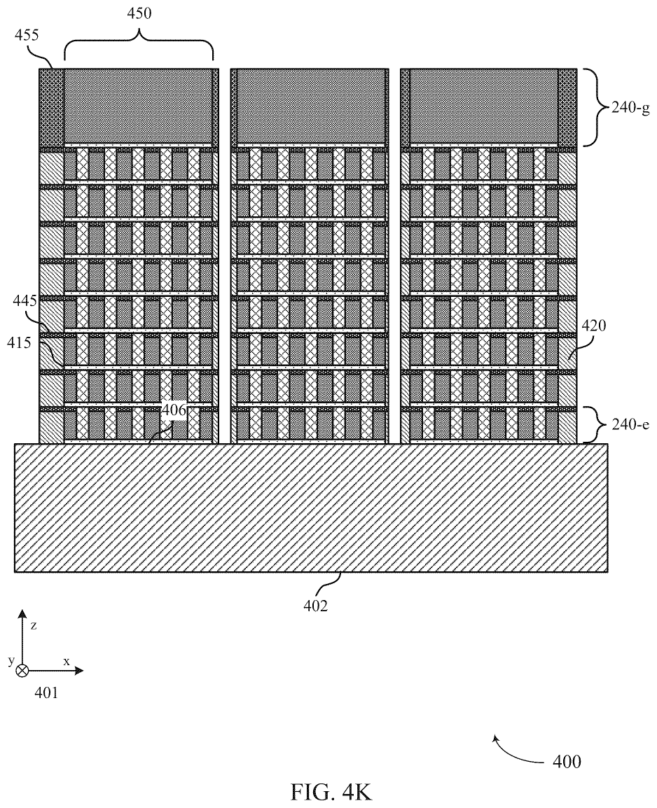

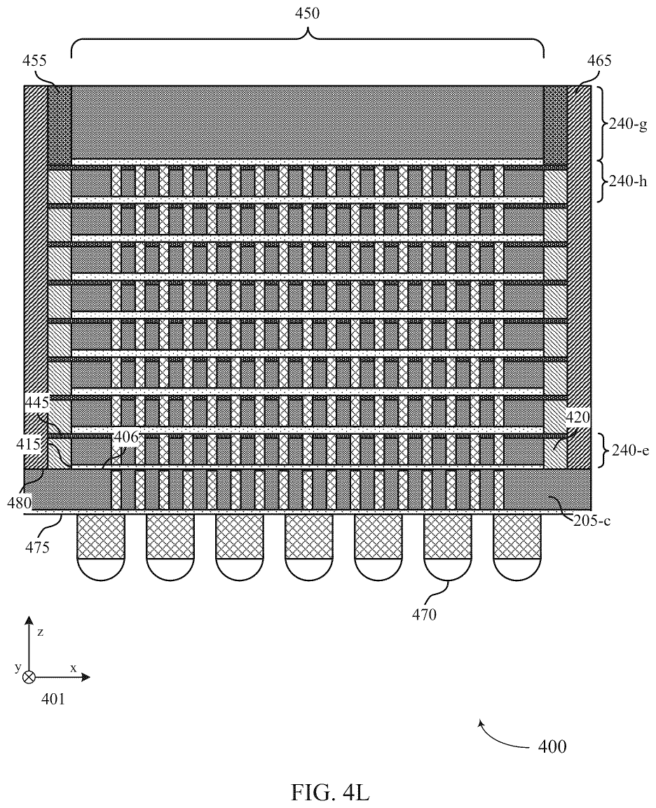

FIGS. 4A through 4L illustrate examples of operations that support hybrid bonding techniques for stacked semiconductor systems in accordance with examples as disclosed herein. Operations are illustrated with reference to device 400, which may be an example of or include an electronic device (e.g., a semiconductor device, a system 100, a memory system 110, a host system 105, a system 200). For example, FIGS. 4A through 4L may illustrate aspects of a second sequence of operations that may support manufacturing a system 100 or a portion thereof, a system 200 or a portion thereof, or some other device. Each of the figures may be described with reference to an x-direction, a y-direction, and a z-direction of a coordinate system 401. Operations illustrated in and described with reference to FIGS. 4A through 4L may be performed by a manufacturing system, such as a semiconductor fabrication system configured to perform additive operations (e.g., deposition, epitaxy, bonding), subtractive operations (e.g., etching, trenching, planarizing, polishing, grinding, scraping), modifying operations (e.g., oxidizing, doping, reacting, converting), and supporting operations (e.g., masking, patterning, photolithography, aligning), among other operations that support the described techniques.

In some examples, portions of the device 400 that are illustrated with a same fill pattern may be formed of same or similar materials and portions that are illustrated with different patterns may be formed of different materials. Various dielectric materials are described herein. Each dielectric material may include a silicon oxide, silicon nitride, a silicon carbon nitride, a tetraethyl orthosilicate (TEOS), some other dielectric material, or any combination thereof. Additionally, conductive materials described herein may include copper, aluminum, tungsten, titanium, some other conductive material, or any combination thereof. In some examples, the mold compound materials described herein may include epoxy-based materials (e.g., epoxy resin, thermoset materials, organic materials).

FIG. 4A shows an example of a cross-sectional view of the device 400 after a first set of one or more fabrication operations. For example, the first operations may include forming a wafer 403 (e.g., a wafer of multiple dies 240). The wafer 403 may include a substrate material (e.g., a semiconductor substrate, one or more semiconductor substrates in accordance with a reconstructed wafer) and may include (e.g., be formed with) one or more conductors 404 and one or more vias 410 (e.g., TSVs) that are formed of one or more conductive materials (e.g., one or more cavities filled with conductive material). The wafer 403 may include a dielectric material 415 (e.g., an example of a dielectric material 242), which may facilitate a bond (e.g., a fusion bond, a hybrid bond) with other dies (e.g., a die 205, a silicon carrier, another die 240).

FIG. 4B shows an example of a cross-sectional view of the device 400 after a second set of one or more fabrication operations. For example, the second operations may include forming a set of dies 240-e (e.g., bottom dies). In some examples, the second operations may include attaching the wafer 403 to an adhesive material 430 (e.g., dicing tape), forming a coating 425 (e.g., a semi-metal coating, such as a coating of a Weyl semi-metal (WSM)) over the dielectric material 415, removing a portion of the coating 425, the dielectric material 415, and the substrate of the wafer 403 (e.g., via laser grooving and plasma dicing). In some examples, the second operations may include a cleaning (e.g., removal) of the coating 425 and a planarization of the dielectric material 415 (e.g., a light CMP). Based on the second operations, dies 240-e may be separated (e.g., via singulation) from other dies 240-e.

FIG. 4C shows an example of a cross-sectional view of the device 400 after a third set of one or more fabrication operations. For example, the third operations may include bonding (e.g., C2W bonding) a surface 406 of a set of dies 240-e (e.g., after singulation) to a surface 440 of a carrier 405 (e.g., a silicon carrier, a sacrificial carrier).

FIG. 4D shows an example of a cross-sectional view of the device 400 after a fourth set of one or more fabrication operations. For example, the fourth operations may include removing (e.g., thinning) a portion of semiconductor substrate of each die 240-e. The fourth operations may also include forming a dielectric material 415 (e.g., gap filling, a first portion of dielectric material) between and over the set of one or more first dies 240-e. In some examples, the dielectric material 415 may extend along a direction (e.g., an x direction) beyond respective semiconductor substrate portions of each die 240-e (e.g., which may include a dual damascene process that forms material a multiple depths). Subsequently, the fourth operations may include removing (e.g., thinning) a portion of respective substrates of the dies 240-e, and planarizing (e.g., CMP, cleaning) the dielectric material 415 (e.g., to be coplanar with the respective substrates of the dies 240-e), and subsequent bonding operations may be based on the planarizing.

FIG. 4E shows an example of a cross-sectional view of the device 400 after a fifth set of one or more fabrication operations. For example, the fifth operations may include removing a portion of the respective semiconductor substrate portions (e.g., silicon etching) of each die 240-e to expose (e.g., reveal) one or more vias 410, or cavities, of the surface 435. The fifth operations may also include forming (e.g., depositing) a dielectric material 420 (e.g., a second portion of a dielectric material) over the dielectric material 415 and over the respective semiconductor substrate portions of the dies 240-e (e.g., which may include a dual damascene process that forms material a multiple depths).

FIG. 4F shows an example of a cross-sectional view of the device 400 after a sixth set of one or more fabrication operations. For example, the sixth operations may include planarizing (e.g., CMP) the dielectric material 420 to expose (e.g., reveal) one or more vias 410, or cavities, of the surface 435 (e.g., to be coplanar with the one or more vias 410). The sixth operations may also include forming (e.g., as part of a dual damascene process) a conductive material in one or more first cavities formed at a first depth in the surface 435 and in one or more second cavities formed at a second depth in the surface 435. In some examples, bonding the dies 240-e with other dies 240 may be based on forming the conductive materials. In some examples, the one or more first cavities may be associated with one or more bonding pads (e.g., hybrid bonding pads), and the one or more second cavities may be associated with one or more vias coupled with the one or more bonding pads and with the vias 410, which may be coupled with circuitry of the respective semiconductor substrate portions of the dies 240-e. In some examples, the sixth operations may also include forming a dielectric material 445 (e.g., a third portion of a dielectric material) over the dielectric material 420. In some examples, forming the dielectric material 445 may also be formed using a dual damascene process (e.g., forming material at multiple depths). In some examples, bonding the set of dies 240-e may be based on forming the conductive materials and forming the dielectric material 445.

FIG. 4G shows an example of a cross-sectional view of the device 400 after a seventh set of one or more fabrication operations. For example, the seventh operations may include bonding (e.g., C2W hybrid bonding) a set of dies 240-f to a surface 435 of the set of dies 240-e that is opposite the surface 406. In some examples, bonding the dies 240-f may be based on bonding a conductive material at the surface 435 to a conductive material of the dies 240-f, and on bonding the dielectric material 445 with a dielectric material 416 of the set of dies 240-f. In some examples, bonding the dies 240-f may be further based on one or more bonding pads (e.g., one or more conductors 404).

FIG. 4H shows an example of a cross-sectional view of the device 400 after an eighth set of one or more fabrication operations. For example, the eighth operations may include removing (e.g., thinning) respective semiconductor respective substrates from each die 240-f, forming (e.g., gap filling) the dielectric material 418 between and over each die 240-f, where the dielectric material 418 extends along the direction between and beyond respective semiconductor substrate portions of the dies 240-f. In some examples, the eighth operations may also include removing (e.g., silicon etching) a portion of the respective substrates to expose (e.g., TSV reveal) one or more vias 410 of the dies 240-f. In some examples, the eighth set of operations may include forming a dielectric material 422 over the dielectric material 418 and over each die 240-f.

FIG. 4I shows an example of a cross-sectional view of the device 400 after a ninth set of one or more fabrication operations. For example, the ninth operations may include forming a dielectric material 460 over the dielectric material 422, which may extend (e.g., span) along a lateral dimension of the dielectric material 422. In some examples, the dielectric material 460 may be formed using a dual damascene process, and the dielectric material 460 and the dielectric material 445 may enclose the dielectric material 418 (e.g., a gap fill layer) on two sides. In some examples, the ninth set of operations may also include a dual damascene procedure to form various contacts (e.g., bond pads, TSVs, other vias) that support bonding between dies 240.

FIG. 4J shows an example of a cross-sectional view of the device 400 after a tenth set of one or more fabrication operations. For example, the tenth operations may include repeating the operations of FIGS. 4G through 4I (or other techniques described herein) to form a stack 450 including multiple die layers of dies 240. Each layer or each set of dies die 240 (e.g., excluding a set of dies 240-g, top dies) may be respectively associated with a dielectric material 415, a dielectric material 420, and a dielectric material 445. In some examples, most of the dies 240 (e.g., all dies 240 of the stack except dies 240-g) may be bonded in accordance with a W2W bonding, and other dies 240 (e.g., the dies 240-g, the top dies) may be bonded in accordance with a C2W bonding. In some examples, a set of dies 240-g (e.g., top dies in the stack 450) may be relatively thicker than other dies 240 (e.g., to meet a height expectation, to improve structural integrity). In some examples, the tenth set of operations may include forming a mold compound material 455 over the dies 240. The mold compound material 455 may extend along the direction (e.g., an x direction) beyond respective semiconductor substrate portions of each of die 240.

FIG. 4K shows an example of a cross-sectional view of the device 400 after an eleventh first set of one or more fabrication operations. For example, the eleventh operations may include removing the carrier 405 (e.g., a frontside carrier) to expose the surface 406 of the dies 240-e. In some examples, the eleventh operations may include removing (e.g., dicing) a portion of the dielectric materials 415, the dielectric materials 420, and the dielectric materials 445 of each layer. Based on the removal of dielectric materials, a stack 450 of dies 240 may be separated from other stacks 450 of dies 240 (e.g., singulation of stacks 450). In some examples, respective surfaces 406 of each die 240-e may be planarized (e.g., via light CMP) in preparation for a bonding operation, and a portion of the mold compound material 455 may be removed (e.g., to be coplanar with the dies 240-g).

In some examples, the eleventh operations may include bonding (e.g., stack-to-wafer (S2W) bonding), after removing the carrier 405, each stack 450 of dies 240 to a wafer 402, which may include multiple logic dies (e.g., dies 205). In some examples, bonding the stack 450 of dies 240 to the wafer 402 may be based on bonding a conductive material at the surface 406 to a conductive material of the wafer 402, and on bonding the dielectric material 415 at the surface 406 a dielectric material of the wafer 402 (e.g., C2W hybrid bonding). Additionally, or alternatively, bonding the stack 450 of dies 240 to the wafer 402 may be based on bonding one or more conductive contacts (e.g., solder ball contacts) formed at the surface 406 to one or more conductive contacts (e.g., solder balls contacts) of the wafer 402 (e.g., chip-on-wafer (CoW) with solder bonding).

FIG. 4L shows an example of a cross-sectional view of a device 400 after a twelfth set of one or more fabrication operations. For example, the twelfth operations may include separating each stack 450 (e.g., by removing or dicing a portion of the wafer 402). In some examples, the twelfth operations may include forming a mold compound material 465 over (e.g., in contact with) the mold compound material 455, the stack 450 of dies 240, the respective dielectric materials (e.g., respective dielectric materials 420, respective dielectric materials 445, respective dielectric materials 415) of each die 240, and the logic die 205-c. The mold compound material 465 may be planarized (e.g., to be coplanar with a die 240-g on top of the stack 450). In some examples, the twelfth operations may include forming one or more conductive contacts 470 (e.g., including a solder material portion and a conductive pillar portion) on a surface 475 of the die 205-c opposite a surface 480 that is bonded with the surface 406 of the set of dies 240-e.

Thus, based on the manufacturing operations described herein, a device 400 (e.g., one or more systems 200 from a device 400) may be fabricated to include a stack 450 of dies 240, where each die 240 of the stack 450 is bonded with at least one other die 240 in the stack 450. The device 400 may include various dielectric material portions (e.g., dielectric materials 420, dielectric materials 415, and dielectric materials 445), and at least some of the dielectric material (e.g., the dielectric materials 420) may extend along a direction (e.g., an x direction) beyond a lateral boundary of the stack 450 and from a semiconductor substrate portion of a respective die 240. That is, at least some of the dies 240 in the stack 450 (e.g., die 240-e, die 240-h) may have one or more surfaces (e.g., side surfaces, lateral surfaces) that are in contact with respective dielectric material portions (e.g., dielectric materials 420). The device 400 may include a logic die 205-c bonded with a die 240-e of the stack 450. In some examples, the logic die 205-c may include circuitry operable to facilitate one or more access operations of the dies 240 of the stack 450.

In some examples, the device 400 may include a mold compound material 455 that is in contact with each lateral edge (e.g., respective side surfaces, respective lateral surfaces) of a die 240-g (e.g., a top die) and with portion of a dielectric material 445 of a die 240. For example, the mold compound material 455 may extend (e.g., span) along a direction beyond a lateral boundary of a die 240-h of the stack 450 and may be coextensive with at least one of the dielectric portions (e.g., the dielectric material 445) of the die 240-h, which may be at an end of the stack 450 that is opposite from the die 240-e. Additionally, or alternatively, the device 400 may also include a mold compound material 465 (e.g., a second layer of mold compound material) formed over the stack 450 of dies 240. The mold compound material 465 may be in contact with the mold compound material 455, one or more respective dielectric materials 420. one or more dielectric material 445, and the logic die 205-c. In some examples, the lateral surfaces of the die 240-g may not be in contact with the dielectric material portions (e.g., the dielectric materials 420). Further, the lateral surfaces of other dies 240 (e.g., die 240-e, die 240-h) may be in contact with the dielectric material portions, and the dielectric material portions may be in contact with the mold compound material 465.

In some examples, the device 400 may include dielectric material portions (e.g., dielectric materials 415) that extend along the direction between a first lateral boundary of a respective die 240 and a second lateral boundary of the respective die 240. In some examples, the device 400 may include dielectric material portions (e.g., dielectric materials 445) formed over a respective die 240 and span along the direction between a first lateral boundary of another respective dielectric material portion (e.g., a dielectric material 420) of the respective die 240 and a second lateral boundary the respective dielectric material portion.

In some examples, a bonding of each die 240 of the stack 450 with at least one other die 240 may include a first bonding between respective conductive materials and second bonding between respective dielectric materials of each die 240. In some examples, the dies 240 of the stack 450 may be bonded in accordance with a front-to-back bonding, and the die 240-e may bonded with the logic die 205-c in accordance with a front-to-front bonding. The device 400 may include any quantity of dies 240 including more or fewer dies 240 than shown (e.g., four dies 240, eight dies 240, sixteen dies 240, or some other integer quantity of dies 240).

Accordingly, by implementing one or more techniques herein, a device 300 (e.g., a semiconductor device, one or more systems 200 from a device 400) may be manufactured with increased reliability (e.g., based on reduced particle collection, based on CMP-based particle removal), increased structural integrity, and improved device yield. For example, the described techniques may more-effectively remove (e.g., or otherwise reduce) debris particles during the manufacturing process, thus improving a likelihood of forming reliable electrical connections (e.g., bonds) between respective dies 240 and dies 205. Additionally, the additional mold compound material 465 may provide increased structural integrity for the device 400, which may increase a reliability of the device 400. Moreover, by implementing the described techniques, relatively fewer devices 400 may be rejected during fabrication, which may result in reduced electronic waste and extended the life of electronic devices, among other benefits.

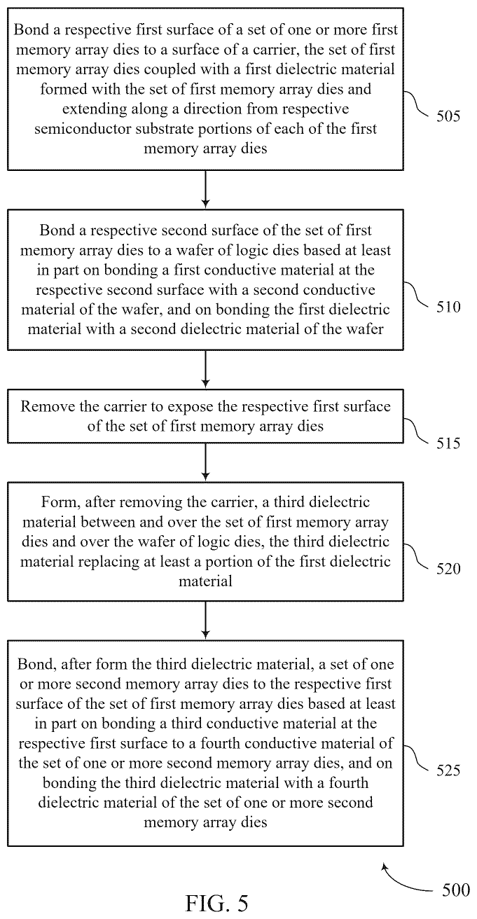

FIG. 5 shows a flowchart illustrating a method or methods 500 that supports hybrid bonding techniques for stacked semiconductor systems in accordance with examples as disclosed herein. The operations of method 500 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 505, the method may include bonding a respective first surface of a set of one or more first memory array dies to a surface of a carrier, the set of first memory array dies coupled with a first dielectric material formed with the set of first memory array dies and extending along a direction from respective semiconductor substrate portions of each of the first memory array dies.

At 510, the method may include bonding a respective second surface of the set of first memory array dies to a wafer of logic dies based at least in part on bonding a first conductive material at the respective second surface with a second conductive material of the wafer, and on bonding the first dielectric material with a second dielectric material of the wafer.

At 515, the method may include removing the carrier to expose the respective first surface of the set of first memory array dies.

At 520, the method may include forming, after removing the carrier, a third dielectric material between and over the set of first memory array dies and over the wafer of logic dies, the third dielectric material replacing at least a portion of the first dielectric material.

At 525, the method may include bonding, after forming the third dielectric material, a set of one or more second memory array dies to the respective first surface of the set of first memory array dies based at least in part on bonding a third conductive material at the respective first surface to a fourth conductive material of the set of one or more second memory array dies, and on bonding the third dielectric material with a fourth dielectric material of the set of one or more second memory array dies.

In some examples, an apparatus (e.g., a manufacturing system) as described herein may perform a method or methods, such as the method 500. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:
Aspect 1: A method or apparatus including operations, features, circuitry, logic, means, or instructions, or any combination thereof for bonding a respective first surface of a set of one or more first memory array dies to a surface of a carrier, the set of first memory array dies coupled with a first dielectric material formed with the set of first memory array dies and extending along a direction from respective semiconductor substrate portions of each of the first memory array dies; bonding a respective second surface of the set of first memory array dies to a wafer of logic dies based at least in part on bonding a first conductive material at the respective second surface with a second conductive material of the wafer, and on bonding the first dielectric material with a second dielectric material of the wafer; removing the carrier to expose the respective first surface of the set of first memory array dies; forming, after removing the carrier, a third dielectric material between and over the set of first memory array dies and over the wafer of logic dies, the third dielectric material replacing at least a portion of the first dielectric material; and bonding, after forming the third dielectric material, a set of one or more second memory array dies to the respective first surface of the set of first memory array dies based at least in part on bonding a third conductive material at the respective first surface to a fourth conductive material of the set of one or more second memory array dies, and on bonding the third dielectric material with a fourth dielectric material of the set of one or more second memory array dies.
Aspect 2: The method or apparatus of aspect 1, further including operations, features, circuitry, logic, means, or instructions, or any combination thereof for removing a portion of the third dielectric material and the fourth dielectric material, where a bonded set of at least one first memory array die and at least one second memory array die is separated from other bonded sets of memory array dies based at least in part on the removing.
Aspect 3: The method or apparatus of any of aspects 1 through 2, further including operations, features, circuitry, logic, means, or instructions, or any combination thereof for forming, prior to bonding the respective first surface, the set of one or more first memory array dies on a second carrier; forming the first dielectric material between and over the set of one or more first memory array dies; and planarizing the first dielectric material, where bonding the respective second surface to the surface of the carrier is based at least in part on the planarizing.
Aspect 4: The method or apparatus of any of aspects 1 through 3, further including operations, features, circuitry, logic, means, or instructions, or any combination thereof for removing, prior to forming the third dielectric material, a portion of the respective semiconductor substrate portions of each first memory array die to expose one or more vias of the respective first surface and forming, after removing the portion the respective semiconductor substrate portions, the third conductive material in one or more first cavities formed at a first depth in the respective first surface and in one or more second cavities formed at a second depth in the respective first surface, where bonding the set of one or more second memory array dies is based at least in part on forming the third conductive material.
Aspect 5: The method or apparatus of aspect 4, where the one or more first cavities are associated with one or more bonding pads; the one or more second cavities are associated with one or more vias coupled with the one or more bonding pads and with circuitry of the respective semiconductor substrate portions; and bonding the one or more second memory array dies is further based at least in part on the one or more bonding pads.
Aspect 6: The method or apparatus of any of aspects 1 through 5, further including operations, features, circuitry, logic, means, or instructions, or any combination thereof for forming, after removing a portion of the third dielectric material and the fourth dielectric material, a mold compound over a bonded set of the set of one or more first memory array dies, a logic die of the wafer of logic dies, and the set of one or more second memory array dies.
Aspect 7: The method or apparatus of any of aspects 1 through 6, further including operations, features, circuitry, logic, means, or instructions, or any combination thereof for forming one or more conductive contacts on a first surface of the wafer of logic dies opposite a second surface of the wafer of logic dies that is bonded with the respective first surface of the set of one or more first memory array dies.

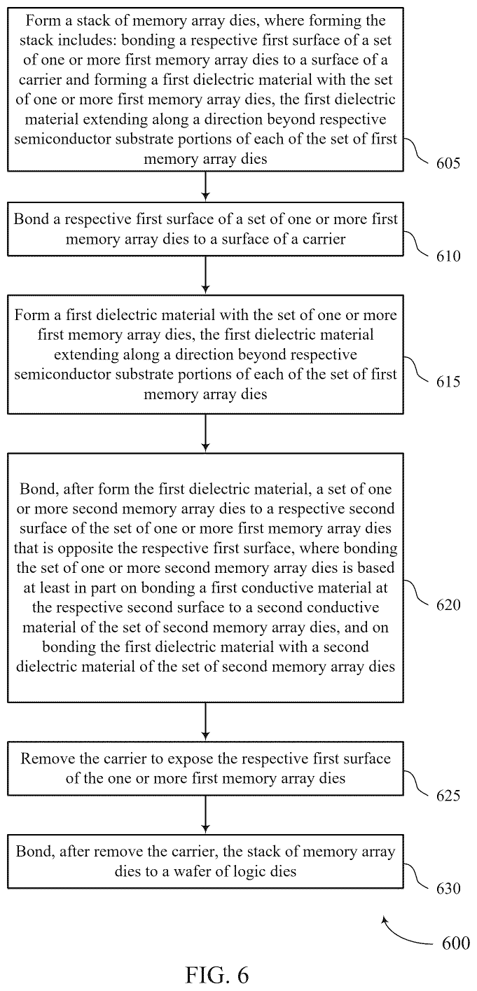

FIG. 6 shows a flowchart illustrating a method or methods 600 that supports hybrid bonding techniques for stacked semiconductor systems in accordance with examples as disclosed herein. The operations of method 600 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 605, the method may include forming a stack of memory array dies, where forming the stack includes: bonding a respective first surface of a set of one or more first memory array dies to a surface of a carrier; and forming a first dielectric material with the set of one or more first memory array dies, the first dielectric material extending along a direction beyond respective semiconductor substrate portions of each of the set of first memory array dies.

At 610, the method may include bonding a respective first surface of a set of one or more first memory array dies to a surface of a carrier.

At 615, the method may include forming a first dielectric material with the set of one or more first memory array dies, the first dielectric material extending along a direction beyond respective semiconductor substrate portions of each of the set of first memory array dies.

At 620, the method may include bonding, after forming the first dielectric material, a set of one or more second memory array dies to a respective second surface of the set of one or more first memory array dies that is opposite the respective first surface, where bonding the set of one or more second memory array dies is based at least in part on bonding a first conductive material at the respective second surface to a second conductive material of the set of second memory array dies, and on bonding the first dielectric material with a second dielectric material of the set of second memory array dies.

At 625, the method may include removing the carrier to expose the respective first surface of the one or more first memory array dies.

At 630, the method may include bonding, after removing the carrier, the stack of memory array dies to a wafer of logic dies.

In some examples, an apparatus (e.g., a manufacturing system) as described herein may perform a method or methods, such as the method 600. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:
Aspect 8: A method or apparatus including operations, features, circuitry, logic, means, or instructions, or any combination thereof for forming a stack of memory array dies, where forming the stack includes: bonding a respective first surface of a set of one or more first memory array dies to a surface of a carrier; forming a first dielectric material with the set of one or more first memory array dies, the first dielectric material extending along a direction beyond respective semiconductor substrate portions of each of the set of first memory array dies; bonding, after forming the first dielectric material, a set of one or more second memory array dies to a respective second surface of the set of one or more first memory array dies that is opposite the respective first surface, where bonding the set of one or more second memory array dies is based at least in part on bonding a first conductive material at the respective second surface to a second conductive material of the set of second memory array dies, and on bonding the first dielectric material with a second dielectric material of the set of second memory array dies; removing the carrier to expose the respective first surface of the one or more first memory array dies; and bonding, after removing the carrier, the stack of memory array dies to a wafer of logic dies.
Aspect 9: The method or apparatus of aspect 8, where removing a portion of the first dielectric material and a portion of the second dielectric material of the set of one or more second memory array dies, where the one or more first memory array dies and the one or more second memory array dies are separated from other sets of memory array dies based at least in part on the removing.
Aspect 10: The method or apparatus of any of aspects 8 through 9, where forming the first dielectric material includes operations, features, circuitry, logic, means, or instructions, or any combination thereof for forming a first portion of the first dielectric material; removing, prior bonding the set of one or more second memory array dies, a portion of the respective semiconductor substrate portions of each first memory array die and a portion of the first dielectric material; and forming a second portion of the first dielectric material over the first portion and over the respective semiconductor substrate portions.
Aspect 11: The method or apparatus of any of aspects 8 through 10, where forming the first dielectric material includes operations, features, circuitry, logic, means, or instructions, or any combination thereof for planarizing, prior bonding the set of one or more second memory array dies, a portion of the first dielectric material to expose one or more vias of the respective second surface; forming the first conductive material in one or more first cavities formed at a first depth in the respective second surface and in one or more second cavities formed at a second depth in the respective second surface; and forming a third portion of the first dielectric material, where bonding the set of one or more second memory array dies is based at least in part on forming the first conductive material and forming the third portion of the first dielectric material.
Aspect 12: The method or apparatus of aspect 11, where the one or more first cavities are associated with one or more bonding pads; the one or more second cavities are associated with one or more vias coupled with the one or more bonding pads and with circuitry of the respective semiconductor substrate portions; and bonding the set of one or more second memory array dies is further based at least in part on the one or more bonding pads.
Aspect 13: The method or apparatus of any of aspects 8 through 12, further including operations, features, circuitry, logic, means, or instructions, or any combination thereof for forming a third dielectric material between and over each memory array die of the set of one or more second memory array dies, the third dielectric material extending along the direction between and beyond respective semiconductor substrate portions of the set of one or more second memory array dies and bonding, after forming the third dielectric material, a set of one or more third memory array dies to a respective first surface of the set of second memory array dies that is opposite a respective second surface of the set of second memory array dies that is bonded with the set of first memory array dies.
Aspect 14: The method or apparatus of any of aspects 8 through 13, further including operations, features, circuitry, logic, means, or instructions, or any combination thereof for forming a mold compound material over the set of second memory array dies, the mold compound material extending along the direction beyond respective semiconductor substrate portions of each of the second memory array dies.
Aspect 15: The method or apparatus of any of aspects 8 through 14, where bonding the stack of dies to the wafer is based at least in part on bonding a third conductive material at the respective first surface to a fourth conductive material of the wafer, and on bonding the first dielectric material at the respective first surface with a fourth dielectric material of the wafer.
Aspect 16: The method or apparatus of any of aspects 8 through 15, where bonding the stack of dies to the wafer is based at least in part on bonding one or more first conductive contacts at the first surface to one or more second conductive contacts of the wafer.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:
Aspect 17: A semiconductor device, including: a stack of memory array dies, where each memory array die of the stack is bonded with at least one other memory array die in the stack; a plurality of dielectric material portions, each of the plurality of dielectric material portions extending along a direction beyond a lateral boundary of the stack and from a respective semiconductor substrate portion of a corresponding one of the memory array dies; and a logic die bonded with a first memory array die of the stack, the logic die including circuitry operable to facilitate one or more access operations of the memory array dies of the stack.
Aspect 18: The semiconductor device of aspect 17, further including: a mold compound formed over the stack of memory array dies, the plurality of dielectric material portions, and the logic die.
Aspect 19: The semiconductor device of any of aspects 17 through 18, where the stack of memory array dies includes a second memory array die that is in direct contact with the mold compound and that is not in contact with the plurality of dielectric material portions.
Aspect 20: The semiconductor device of any of aspects 17 through 18, further including: a first mold compound extending along the direction beyond a lateral boundary of a second memory array die of the stack and coextensive with at least one of the plurality of dielectric portions, the second memory array die at an end of the stack that is opposite from the first memory array die; and a second mold compound formed over the first mold compound, the stack of memory array dies, the plurality of dielectric material portions, and the logic die.
Aspect 21: The semiconductor device of any of aspects 17 through 20, further including: a plurality of second dielectric material portions, each of the plurality of second dielectric material portions extending along the direction between a first lateral boundary of a corresponding one of the memory array dies and a second lateral boundary of the corresponding one of the memory array dies.
Aspect 22: The semiconductor device of any of aspects 17 through 21, further including: a plurality of third dielectric material portions, each of the plurality of third dielectric material portions formed over a respective one of the memory array dies and extending along the direction between a first lateral boundary of a respective dielectric material portion of the respective memory array die and a second lateral boundary the respective dielectric material portion.
Aspect 23: The semiconductor device of any of aspects 17 through 22, where the bonding of each memory array die of the stack with the at least one other memory array die includes first bonding between respective conductive materials and second bonding between respective dielectric materials.
Aspect 24: The semiconductor device of any of aspects 17 through 23, where: the memory array dies of the stack are bonded in accordance with a front-to-back bonding; and the first memory array die is bonded with the logic die in accordance with a front-to-front bonding.
Aspect 25: The semiconductor device of any of aspects 17 through 24, further including: one or more conductive contacts formed at a first surface of the logic die that is opposite a second surface if the logic die that is bonded with the stack.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

Some examples and operations described herein may be described with reference to various sides of a respective component. For example, a side of a component may be referred to as a “backside” or “back,” or a “frontside” or “front.” A frontside of a semiconductor device may refer to a side that includes components such as transistors and capacitors. The frontside may also include an electrically conductive metallization structure with chip contact areas. The frontside may include front end of line (FEOL), middle of line (MOL), and back end of line (BEOL) layers. The frontside may face up during the manufacturing process and may be the primary surface for the device's operation. On the other hand, a backside of a semiconductor device may refer to a side that is opposite to where the main functional elements are located. The backside may be used for various supporting functions that complement the frontside. In some examples, the frontside may be opposite a substrate material on which the device was formed (e.g., opposite of a backside). In some examples, the backside may be a same side as a substrate material (e.g., a silicon substrate) on which the component was formed (e.g., a substrate for mechanical support during formation).

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A semiconductor device, comprising:
a stack of memory array dies, wherein each memory array die of the stack is bonded with at least one other memory array die in the stack;
a plurality of dielectric material portions, each of the plurality of dielectric material portions extending along a direction beyond a lateral boundary of the stack and from a respective semiconductor substrate portion of a corresponding one of the memory array dies; and
a logic die bonded with a first memory array die of the stack, the logic die comprising circuitry operable to facilitate one or more access operations of the memory array dies of the stack.

2. The semiconductor device of claim 1, further comprising:
a mold compound formed over the stack of memory array dies, the plurality of dielectric material portions, and the logic die.

3. The semiconductor device of claim 2, wherein the stack of memory array dies includes a second memory array die that is in direct contact with the mold compound and that is not in contact with the plurality of dielectric material portions.

4. The semiconductor device of claim 1, further comprising:
a first mold compound extending along the direction beyond a lateral boundary of a second memory array die of the stack and coextensive with at least one of the plurality of dielectric portions, the second memory array die at an end of the stack that is opposite from the first memory array die; and
a second mold compound formed over the first mold compound, the stack of memory array dies, the plurality of dielectric material portions, and the logic die.

5. The semiconductor device of claim 1, further comprising:
a plurality of second dielectric material portions, each of the plurality of second dielectric material portions extending along the direction between a first lateral boundary of a corresponding one of the memory array dies and a second lateral boundary of the corresponding one of the memory array dies.

6. The semiconductor device of claim 1, further comprising:
a plurality of third dielectric material portions, each of the plurality of third dielectric material portions formed over a respective one of the memory array dies and extending along the direction between a first lateral boundary of a respective dielectric material portion of the respective memory array die and a second lateral boundary the respective dielectric material portion.

7. The semiconductor device of claim 1, wherein the bonding of each memory array die of the stack with the at least one other memory array die comprises first bonding between respective conductive materials and second bonding between respective dielectric materials.

8. The semiconductor device of claim 1, wherein:
the memory array dies of the stack are bonded in accordance with a front-to-back bonding; and
the first memory array die is bonded with the logic die in accordance with a front-to-front bonding.

9. The semiconductor device of claim 1, further comprising:
one or more conductive contacts formed at a first surface of the logic die that is opposite a second surface if the logic die that is bonded with the stack.

10. A method for semiconductor device manufacture, comprising:
bonding a respective first surface of a set of one or more first memory array dies to a surface of a carrier, the set of first memory array dies coupled with a first dielectric material formed with the set of first memory array dies and extending along a direction from respective semiconductor substrate portions of each of the first memory array dies;
bonding a respective second surface of the set of first memory array dies to a wafer of logic dies based at least in part on bonding a first conductive material at the respective second surface with a second conductive material of the wafer, and on bonding the first dielectric material with a second dielectric material of the wafer;
removing the carrier to expose the respective first surface of the set of first memory array dies;
forming, after removing the carrier, a third dielectric material between and over the set of first memory array dies and over the wafer of logic dies, the third dielectric material replacing at least a portion of the first dielectric material; and
bonding, after forming the third dielectric material, a set of one or more second memory array dies to the respective first surface of the set of first memory array dies based at least in part on bonding a third conductive material at the respective first surface to a fourth conductive material of the set of one or more second memory array dies, and on bonding the third dielectric material with a fourth dielectric material of the set of one or more second memory array dies.

11. The method of claim 10, further comprising:
removing a portion of the third dielectric material and the fourth dielectric material, wherein a bonded set of at least one first memory array die and at least one second memory array die is separated from other bonded sets of memory array dies based at least in part on the removing.

12. The method of claim 10, further comprising:
forming, prior to bonding the respective first surface, the set of one or more first memory array dies on a second carrier;
forming the first dielectric material between and over the set of one or more first memory array dies; and
planarizing the first dielectric material, wherein bonding the respective second surface to the surface of the carrier is based at least in part on the planarizing.

13. The method of claim 10, further comprising:
removing, prior to forming the third dielectric material, a portion of the respective semiconductor substrate portions of each first memory array die to expose one or more vias of the respective first surface; and
forming, after removing the portion the respective semiconductor substrate portions, the third conductive material in one or more first cavities formed at a first depth in the respective first surface and in one or more second cavities formed at a second depth in the respective first surface, wherein bonding the set of one or more second memory array dies is based at least in part on forming the third conductive material.

14. The method of claim 13, wherein:
the one or more first cavities are associated with one or more bonding pads;
the one or more second cavities are associated with one or more vias coupled with the one or more bonding pads and with circuitry of the respective semiconductor substrate portions; and
bonding the one or more second memory array dies is further based at least in part on the one or more bonding pads.

15. The method of claim 10, further comprising:
forming, after removing a portion of the third dielectric material and the fourth dielectric material, a mold compound over a bonded set of the set of one or more first memory array dies, a logic die of the wafer of logic dies, and the set of one or more second memory array dies.

16. The method of claim 10, further comprising:
forming one or more conductive contacts on a first surface of the wafer of logic dies opposite a second surface of the wafer of logic dies that is bonded with the respective first surface of the set of one or more first memory array dies.

17. A method for semiconductor device manufacture, comprising:
forming a stack of memory array dies, wherein forming the stack comprises:
bonding a respective first surface of a set of one or more first memory array dies to a surface of a carrier;
forming a first dielectric material with the set of one or more first memory array dies, the first dielectric material extending along a direction beyond respective semiconductor substrate portions of each of the set of first memory array dies; and
bonding, after forming the first dielectric material, a set of one or more second memory array dies to a respective second surface of the set of one or more first memory array dies that is opposite the respective first surface, wherein bonding the set of one or more second memory array dies is based at least in part on bonding a first conductive material at the respective second surface to a second conductive material of the set of second memory array dies, and on bonding the first dielectric material with a second dielectric material of the set of second memory array dies;
removing the carrier to expose the respective first surface of the one or more first memory array dies; and
bonding, after removing the carrier, the stack of memory array dies to a wafer of logic dies.

18. The method of claim 17, wherein forming the stack further comprises:
removing a portion of the first dielectric material and a portion of the second dielectric material of the set of one or more second memory array dies, wherein the one or more first memory array dies and the one or more second memory array dies are separated from other sets of memory array dies based at least in part on the removing.

19. The method of claim 17, wherein forming the first dielectric material comprises:
forming a first portion of the first dielectric material;
removing, prior bonding the set of one or more second memory array dies, a portion of the respective semiconductor substrate portions of each first memory array die and a portion of the first dielectric material; and
forming a second portion of the first dielectric material over the first portion and over the respective semiconductor substrate portions.

20. The method of claim 17, wherein forming the first dielectric material comprises:
planarizing, prior bonding the set of one or more second memory array dies, a portion of the first dielectric material to expose one or more vias of the respective second surface;
forming the first conductive material in one or more first cavities formed at a first depth in the respective second surface and in one or more second cavities formed at a second depth in the respective second surface; and
forming a third portion of the first dielectric material, wherein bonding the set of one or more second memory array dies is based at least in part on forming the first conductive material and forming the third portion of the first dielectric material.

21. The method of claim 20, wherein:
the one or more first cavities are associated with one or more bonding pads;
the one or more second cavities are associated with one or more vias coupled with the one or more bonding pads and with circuitry of the respective semiconductor substrate portions; and
bonding the set of one or more second memory array dies is further based at least in part on the one or more bonding pads.

22. The method of claim 17, further comprising:
forming a third dielectric material between and over each memory array die of the set of one or more second memory array dies, the third dielectric material extending along the direction between and beyond respective semiconductor substrate portions of the set of one or more second memory array dies; and
bonding, after forming the third dielectric material, a set of one or more third memory array dies to a respective first surface of the set of second memory array dies that is opposite a respective second surface of the set of second memory array dies that is bonded with the set of first memory array dies.

23. The method of claim 17, further comprising:
forming a mold compound material over the set of second memory array dies, the mold compound material extending along the direction beyond respective semiconductor substrate portions of each of the second memory array dies.

24. The method of claim 17, wherein bonding the stack of dies to the wafer is based at least in part on bonding a third conductive material at the respective first surface to a fourth conductive material of the wafer, and on bonding the first dielectric material at the respective first surface with a fourth dielectric material of the wafer.

25. The method of claim 17, wherein bonding the stack of dies to the wafer is based at least in part on bonding one or more first conductive contacts at the first surface to one or more second conductive contacts of the wafer.
